(19) United States
(12) Patent Application Publication
(10) Pub. No.: US 2025/0046769 A1
(43) Pub. Date: Feb. 6, 2025

(54) SEMICONDUCTOR PACKAGE

(71) Applicant: Samsung Electronics Co., Ltd., Suwon-sI (KR)

(72) Inventors: Jooyoung CHOI, Suwon-si (KR); Dahee KIM, Suwon-si (KR); Jeongseok KIM, Suwon-si (KR); Gyujin CHOI, Suwon-si (KR); Jaehoon CHOI, Suwon-si (KR)

(73) Assignee: Samsung Electronics Co., Ltd., Suwon-si (KR)

(21) Appl. No.: 18/665,893

(22) Filed: May 16, 2024

(30) Foreign Application Priority Data
Jul. 31, 2023 (KR) 10-2023-0099832

(51) Int. Cl. H01L 25/10; H01L 23/00; H01L 23/31; H01L 23/498; H01L 25/065; H01L 25/16

(52) U.S. Cl. CPC H01L 25/105; H01L 23/3135; H01L 23/49822; H01L 23/49833; H01L 23/49838; H01L 25/0652; H01L 23/49816; H01L 24/08; H01L 24/16; H01L 24/32; H01L 24/48; H01L 24/73; H01L 25/165; H01L 2224/08235; H01L 2224/16227; H01L 2224/32225; H01L 2224/48227; H01L 2224/73204; H01L 2224/73265; H01L 2225/1023; H01L 2225/1035; H01L 2225/1058; H01L 2924/15174

(57) ABSTRACT

A semiconductor package may include a package redistribution layer including a plurality of package redistribution patterns and a package redistribution insulating layer surrounding the plurality of package redistribution patterns, a plurality of electronic components apart from each other in a horizontal direction on the package redistribution layer and including at least one sub package, a package molding layer covering a top surface of the package redistribution layer and surrounding the plurality of electronic components, and a plurality of package connection terminals attached to a bottom surface of the package redistribution layer in a fan-out manner. The at least one sub package may include a package substrate, a semiconductor chip attached to the package substrate, and a sub molding layer on the package substrate.

### CROSS-REFERENCE TO RELATED APPLICATION

This application is based on and claims priority under 35 U.S.C. § 119 to Korean Patent Application No. 10-2023-0099832, filed on Jul. 31, 2023 in the Korean Intellectual Property Office, the disclosure of which is incorporated by reference herein in its entirety.

### BACKGROUND

Inventive concepts relate to a semiconductor package, and more particularly, to a semiconductor package of a package-in-package (PiP) type and a package-on-package (PoP) including the same.

With the rapid development of the electronics industry and users' needs, electronic equipment has become compact and multifunctionalized, and electronic equipment may have a high capacity. Accordingly, semiconductor packages included in electronic equipment may be required to provide more functions. Accordingly, a PiP, in which various electronic components including at least one sub package are mounted on a single semiconductor package, and a PoP, in which an upper package is attached to a lower package, have been developed.

### SUMMARY

Inventive concepts provide a package-in-package (PiP)-type semiconductor package, which is miniaturized and enables flexible form factor changes, and a package-on-package (PoP)-type semiconductor package including the same.

According to an embodiment of inventive concepts, a semiconductor package may include a package redistribution layer including a plurality of package redistribution patterns and a package redistribution insulating layer surrounding the plurality of package redistribution patterns; a plurality of electronic components apart from each other in a horizontal direction on the package redistribution layer, the plurality of electronic components include a sub package; a package molding layer covering a top surface of the package redistribution layer and surrounding the plurality of electronic components; and a plurality of package connection terminals attached to a bottom surface of the package redistribution layer in a fan-out manner. The sub package may include a package substrate corresponding to a printed circuit board, a semiconductor chip attached to the package substrate, and a sub molding layer on the package substrate. The package substrate may include a base insulating layer, package upper pads on a top surface of the base insulating layer and package lower pads on a bottom surface of the base insulating layer. The semiconductor chip may include a plurality of chip pads electrically connected to the package upper pads. The sub molding layer may cover the semiconductor chip. The package lower pads respectively may be in contact with and electrically connected to the plurality of package redistribution patterns.

According to an embodiment of inventive concepts, a semiconductor package may include a package redistribution layer including a plurality of package redistribution patterns and a package redistribution insulating layer surrounding the plurality of package redistribution patterns; a plurality of sub packages apart from each other in a horizontal direction on the package redistribution layer, the plurality of sub packages including two sub packages apart from each other in the horizontal direction on the package redistribution layer; a package molding layer covering a top surface of the package redistribution layer and surrounding the plurality of sub packages; and a plurality of package connection terminals attached to a bottom surface of the package redistribution layer in a fan-out manner. Each sub package of the plurality of sub packages may include a package substrate, a semiconductor chip attached to the package substrate, and a sub molding layer on the package substrate. The package substrate may include a base insulating layer, package upper pads on a top surface of the base insulating layer, package lower pads on a bottom surface of the base insulating layer, and a bottom solder resist layer. The bottom solder resist layer may cover the bottom surface of the base insulating layer and does not cover the package lower pads. The semiconductor chip may include a plurality of chip pads electrically connected to the package upper pads. The sub molding layer may cover the semiconductor chip. The package lower pads respectively may be in contact with and electrically connected to the plurality of package redistribution patterns. A portion of each of the package lower pads may be in contact with the package redistribution insulating layer.

According to an embodiment of inventive concepts, a semiconductor package may include a lower package; and an upper package attached to the lower package. The lower package may include a first wiring structure, a second wiring structure on the first wiring structure, a lower semiconductor chip between the first wiring structure and the second wiring structure, and an expansion layer surrounding the lower semiconductor chip. The first wiring structure may include a plurality of first redistribution patterns and a plurality of first redistribution insulating layers surrounding the plurality of first redistribution patterns. The second wiring structure may include a plurality of second redistribution patterns and a plurality of second redistribution insulating layers surrounding the plurality of second redistribution patterns. The expansion layer may electrically connect the plurality of first redistribution patterns to the plurality of second redistribution patterns. The upper package may include a package redistribution layer including a plurality of package redistribution patterns and a package redistribution insulating layer surrounding the plurality of package redistribution patterns, a plurality of electronic components apart from each other in a horizontal direction on the package redistribution layer and including a sub package, a package molding layer covering a top surface of the package redistribution layer and surrounding the plurality of electronic components, and a plurality of package connection terminals electrically connecting the lower package to the upper package and attached to a bottom surface of the package redistribution layer in a fan-out manner. The sub package may include a package substrate corresponding to a printed circuit board, a semiconductor chip attached to the package substrate, and a sub molding layer on the package substrate. The package substrate may include a base insulating layer, package upper pads on a top surface of the base insulating layer, package lower pads on a bottom surface of the base insulating layer, a plurality of via patterns passing through the base insulating layer and electrically connecting the package upper pads to the package lower pads, and a bottom solder resist layer covering the bottom surface of the base insulating layer but not covering the package lower pads. The semiconductor chip may include a plurality of chip pads electrically connected to the package upper pads. The sub molding layer may cover the semiconductor chip. The package redistribution insulating layer may cover a lower side surface of the package substrate. The package molding layer may cover an upper side surface of the package substrate.

### BRIEF DESCRIPTION OF THE DRAWINGS

Embodiments will be more clearly understood from the following detailed description taken in conjunction with the accompanying drawings in which:

FIGS. 1A to 1D are cross-sectional views illustrating a method of manufacturing a package-in-package (PiP)-type semiconductor package, according to embodiments;

FIG. 2A is a cross-sectional view of a PiP-type semiconductor package according to embodiments and FIG. 2B is an enlarged view of a region IIB in FIG. 2A;

FIG. 3 is a cross-sectional view of a package-on-package (PoP)-type semiconductor package according to embodiments;

FIG. 4 is a cross-sectional view of a PoP-type semiconductor package according to embodiments;

FIG. 5 is a cross-sectional view of a PoP-type semiconductor package according to embodiments;

FIG. 6A is a cross-sectional view illustrating a method of manufacturing a PiP-type semiconductor package, according to embodiments, and FIG. 6B is a cross-sectional view of a PiP-type semiconductor package according to embodiments;

FIG. 7A is a cross-sectional view illustrating a method of manufacturing a PiP-type semiconductor package, according to embodiments, and FIG. 7B is a cross-sectional view of a PiP-type semiconductor package according to embodiments;

FIG. 8 is a cross-sectional view of a PiP-type semiconductor package according to embodiments;

FIG. 9 is a cross-sectional view of a PiP-type semiconductor package according to embodiments;

FIGS. 10, 11A, and 11B are cross-sectional views of PiP-type semiconductor packages according to embodiments; and

FIGS. 12, 13A, and 13B are cross-sectional views of PiP-type semiconductor packages according to embodiments.

### DETAILED DESCRIPTION

As used herein, the singular forms “a,” “an” and “the” are intended to include the plural forms as well, unless the context clearly indicates otherwise. The singular form of a constituent element may include a plurality of the constituent elements unless the context clearly indicates otherwise.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

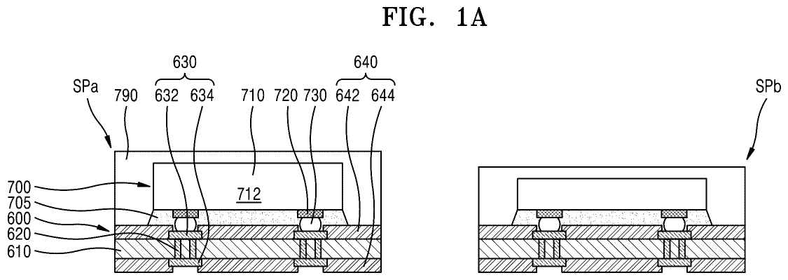

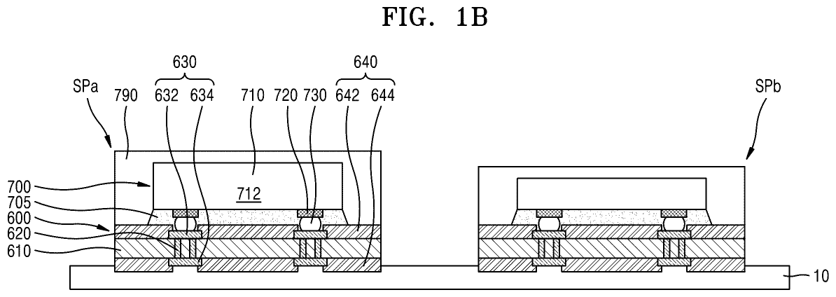

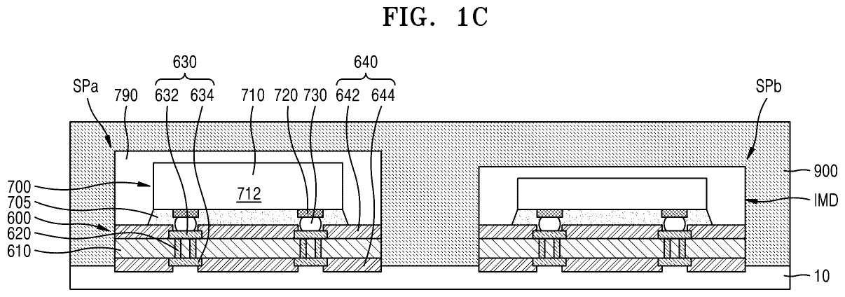

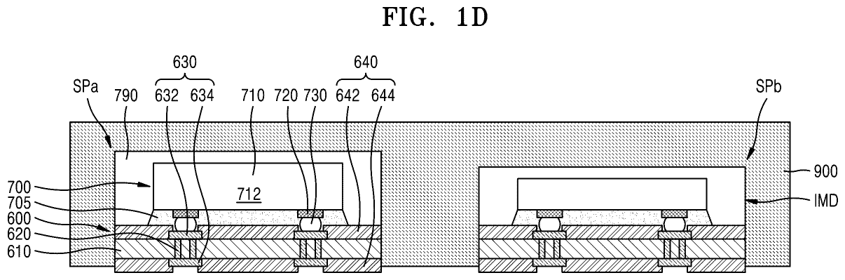

FIGS. 1A to 1D are cross-sectional views illustrating a method of manufacturing a package-in-package (PiP)-type semiconductor package, according to embodiments.

Referring to FIG. 1A, a plurality of electronic components including a first sub package SPa and a second sub package SPb may be prepared. Each of the first sub package SPa and the second sub package SPb may include a package substrate 600, at least one semiconductor chip 700 attached to the package substrate 600, and a sub molding layer 790, which is on the package substrate 600 and covers the semiconductor chip 700.

The package substrate 600 may include a printed circuit board (PCB). The package substrate 600 may include, but not limited to, a double-sided PCB. For example, the package substrate 600 may include a multi-layer PCB. The package substrate 600 may include at least one base insulating layer 610, a plurality of via patterns 620, and a plurality of wiring patterns 630.

The wiring patterns 630 may include a plurality of top conductive patterns 632 and a plurality of bottom conductive patterns 634. The top conductive patterns 632 may be disposed on the top surface of the base insulating layer 610. The bottom conductive patterns 634 may be disposed on the bottom surface of the base insulating layer 610. The via patterns 620 may pass through the base insulating layer 610 and may be electrically connected to the top conductive patterns 632 and the bottom conductive patterns 634. When the package substrate 600 includes a multi-layer PCB, the package substrate 600 may include a plurality of base insulating layers 610 and the wiring patterns 630 may further include a plurality of inner conductive patterns between two adjacent base insulating layers 610 and each of the via patterns 620 may pass through at least one of the base insulating layers 610 and electrically connect two conductive patterns at different vertical levels among the top conductive patterns 632, the bottom conductive patterns 634, and the inner conductive patterns.

The base insulating layer 610 may include at least one selected from the group consisting of phenol resin, epoxy resin, and polyimide. For example, the base insulating layer 610 may include at least one material selected from the group consisting of flame retardant 4 (FR-4), tetrafunctional epoxy, polyphenylene ether, epoxy/polyphenylene oxide, bismaleimide triazine (BT), thermount, cyanate ester, polyimide, and liquid crystal polymer.

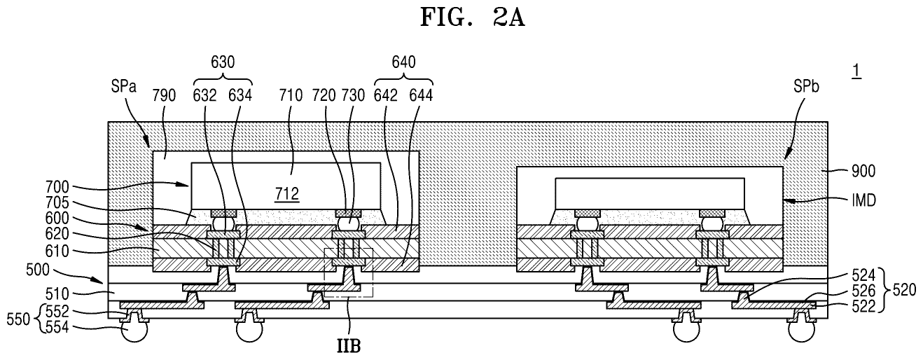

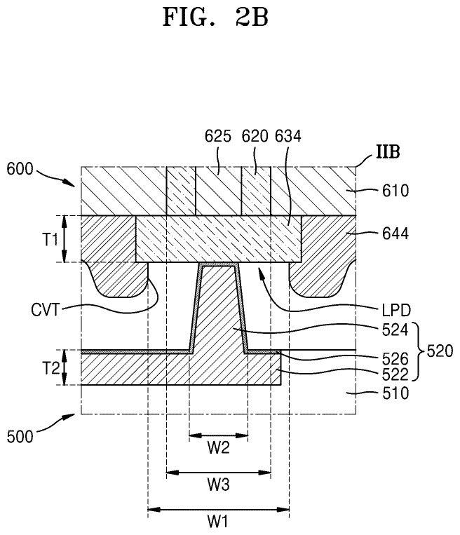

The via patterns 620 may include copper (Cu) or an alloy including Cu. For example, the via patterns 620 may include, but not limited to, Cu, titanium (Ti), titanium tungsten (TiW), titanium nitride (TiN), tantalum (Ta), tantalum nitride (TaN), chrome (Cr), a Cu/Ti structure, in which Cu is stacked on Ti, or a structure, in which Cu or an alloy including Cu is stacked on a seed layer including a Cu/TiW structure in which Cu is stacked on TiW. In some embodiments, each of the via patterns 620 may be formed to cover the inner sidewall of a via through hole, which passes through the base insulating layer 610, and partially fill the via through hole. A via filling insulation layer 625 (in FIG. 2B) may cover each via pattern 620 and fill the via through hole. For example, the via through hole may be completely filled with the via pattern 620 and the via filling insulation layer 625.

The wiring patterns 630 may include electrolytically deposited (ED) copper foil, rolled-annealed (RA) copper foil, stainless steel foil, aluminum foil, ultra-thin copper foil, sputtered copper, or a copper alloy.

The package substrate 600 may include a solder resist layer 640 disposed on the top and bottom surfaces of the package substrate 600. The solder resist layer 640 may include a top solder resist layer 642 on the top surface of the package substrate 600 and a bottom solder resist layer 644 on the bottom surface of the package substrate 600. At least some of the top conductive patterns 632 of the wiring patterns 630 may correspond to package upper pads, which are not covered with the top solder resist layer 642 but exposed on the top surface of the package substrate 600. At least some of the bottom conductive patterns 634 of the wiring patterns 630 may correspond to package lower pads (LPD in FIG. 2B), which are not covered with the bottom solder resist layer 644 but exposed on the bottom surface of the package substrate 600. In some embodiments, the package upper pads and the package lower pads may include Cu. The top surface of each package upper pad may be at a lower vertical level than the topmost end of the top solder resist layer 642 and the bottom surface of each of the package lower pads LPD may be at a higher vertical level than the bottommost end of the bottom solder resist layer 644. A package cavity CVT (in FIG. 2B) may be defined by the bottom solder resist layer 644 between the bottommost end of the bottom solder resist layer 644 and the bottom surface of one of the bottom conductive patterns 634.

The semiconductor chip 700 may be attached to the package substrate 600. The semiconductor chip 700 may include a semiconductor substrate 710 having an active surface and an inactive surface opposite to the active surface, a semiconductor device 712 formed on the active surface of the semiconductor substrate 710, and a plurality of chip pads 720 disposed on the semiconductor device 712. The semiconductor chip 700 may have a first surface and a second surface opposite to the first surface. The chip pads 720 may be disposed on the first surface of the semiconductor chip 700. The second surface of the semiconductor chip 700 may correspond to the inactive surface of the semiconductor substrate 710. The active surface of the semiconductor substrate 710 is very close to the first surface of the semiconductor chip 700 and thus not separately illustrated from the first surface of the semiconductor chip 700 in the drawings.

For example, the semiconductor substrate 710 may include a semiconductor material, such as silicon (Si) or germanium (Ge). For example, the semiconductor substrate 710 may include a compound semiconductor, such as silicon carbide (SiC), gallium arsenide (GaAs), indium arsenide (InAs), or indium phosphide (InP). The semiconductor substrate 710 may include a conductive region, e.g., an impurity-doped well. The semiconductor substrate 710 may have various isolation structures such as a shallow trench isolation (STI) structure.

The semiconductor device 712 including various kinds of individual devices may be on the active surface of the semiconductor substrate 710. The individual devices may include various microelectronic devices, e.g., a metal-oxide-semiconductor field effect transistor (MOSFET) such as a complementary metal-oxide-semiconductor (CMOS) transistor, a system large scale integration (LSI), an active element, and a passive element. The individual devices may be electrically connected to the conductive region of the semiconductor substrate 710. The semiconductor device 712 may further include a conductive plug or conductive wiring, which electrically connects the individual devices or at least two of the individual devices to the conductive region of the semiconductor substrate 710. Each of the individual devices may be electrically separated from other neighboring individual devices by an insulating film.

In some embodiments, the semiconductor chip 700 may include a logic device. For example, the semiconductor chip 700 may include a central processing unit (CPU) chip, a graphics processing unit (GPU) chip, or an application processor (AP) chip. In some embodiments, the semiconductor chip 700 may correspond to a memory semiconductor chip including a memory device. For example, the memory device may include non-volatile memory, such as flash memory, phase-change random access memory (PRAM), magnetoresistive RAM (MRAM), ferroelectric RAM (FeRAM), or resistive RAM (RRAM) chip. For example, the flash memory may include NAND flash memory or vertical NAND (VNAND) flash memory. In some embodiments, the memory device may include volatile memory, such as dynamic RAM (DRAM) chip or static RAM (SRAM). In some embodiments, when the first sub package SPa and/or the second sub package SPb includes a plurality of semiconductor chips 700, at least one of the semiconductor chips 700 may correspond to a CPU chip, a GPU chip, or an AP chip and at least one other semiconductor chip 700 may correspond to a memory semiconductor chip including a memory device.

In some embodiments, a semiconductor chip 700 of the first sub package SPa may include the same type of semiconductor device 712 as a semiconductor chip 700 of the second sub package SPb. In some embodiments, the semiconductor chip 700 of the first sub package SPa may include a different type of semiconductor device 712 than the semiconductor chip 700 of the second sub package SPb. For example, the semiconductor device 712 of the semiconductor chip 700 of the first sub package SPa may be a logic device and the semiconductor device 712 of the semiconductor chip 700 of the second sub package SPb may be a memory device.

In some embodiments, the semiconductor chip 700 may be attached to the top surface of the package substrate 600 in a face-down manner such that the first surface of the semiconductor chip 700 and the active surface of the semiconductor substrate 710 face the package substrate 600. For example, the semiconductor chip 700 may be arranged on the package substrate 600 such that the chip pads 720 face the package substrate 600. In this case, the first surface of the semiconductor chip 700 may be referred to as the bottom surface of the semiconductor chip 700 and the second surface of the semiconductor chip 700 may be referred to as the top surface of the semiconductor chip 700. Herein, the top surface refers to a surface facing upwards in the drawings and the bottom surface refers to a surface facing downwards in the drawings, unless stated otherwise.

A plurality of chip connectors 730 may be between the package upper pads, which correspond to at least some of the top conductive patterns 632, and the chip pads 720. For example, after the chip connectors 730 are respectively attached to the bottom surfaces of the chip pads 720, the semiconductor chip 700 may be attached to the package substrate 600 such that the chip connectors 730 are respectively connected to the package upper pads. Each of the chip connectors 730 may include a bump or a solder ball. In some embodiments, an underfill layer 705 may be between the semiconductor chip 700 and the package substrate 600 to surround the chip connectors 730. For example, the underfill layer 705 may include epoxy resin formed using a capillary underfill process. In some embodiments, the underfill layer 705 may include a non-conductive film (NCF).

The sub molding layer 790 may cover the top surface of the package substrate 600 and surround the semiconductor chip 700. For example, the sub molding layer 790 may correspond to a molding member including an epoxy molding compound (EMC).

Referring to FIG. 1B, the first sub package SPa and the second sub package SPb may be attached to a release film 10. The first sub package SPa and the second sub package SPb may be attached to the release film 10 and separated from each other in a horizontal direction.

In some embodiments, the release film 10 may correspond to a multi-layer film, which includes a backbone layer and a release layer attached to each of opposite surfaces of the backbone layer. The release layer may be referred to as an adhesive layer. For example, the backbone layer may have a thickness of several m to tens of m. For example, the backbone layer may include a thermoplastic polymer. The release layer may have a thickness of hundreds of nm to several m. For example, the release layer may include an acrylic-silicone copolymer. In some embodiments, the release film 10 may correspond to a single film constituted of a release layer including an acrylic-silicone copolymer.

In some embodiments, the release film 10 may fill the package cavity CVT (in FIG. 2B) of each of the first sub package SPa and the second sub package SPb. In some embodiments, the release film 10 may cover a lower side portion of the package substrate 600 of each of the first sub package SPa and the second sub package SPb.

Referring to FIG. 1C, a package molding layer 900 may be formed to cover the top surface of the release film 10 and surround the first sub package SPa and the second sub package SPb. For example, the package molding layer 900 may correspond to a molding member including an EMC. The package molding layer 900 may cover the side surface of each of the first sub package SPa and the second sub package SPb. In some embodiments, the package molding layer 900 may be formed to cover the top surface of each of the first sub package SPa and the second sub package SPb. However, embodiments are not limited thereto.

The package molding layer 900 may be formed to be in contact with the sub molding layer 790 of each of the first sub package SPa and the second sub package SPb. A mold interface IMD may be formed between the package molding layer 900 and the sub molding layer 790. The package molding layer 900 may cover the side surface of the sub molding layer 790. In some embodiments, the package molding layer 900 may be formed to cover the top surface of the sub molding layer 790. However, embodiments are not limited thereto. For example, the package molding layer 900 may entirely cover the side surface of the sub molding layer 790 but may not cover the top surface of the sub molding layer 790.

Referring to FIGS. 1C and 1D, the release film 10 may be removed from the first sub package SPa, the second sub package SPb, and the package molding layer 900. With the removal of the release film 10, the bottom surface of the package substrate 600 may be exposed. For example, as the release film 10 is removed, a package lower pad LPD (in FIG. 2B) in the package cavity CVT (in FIG. 2B) may be exposed. In some embodiments, as the release film 10 is removed, a lower side portion of the package substrate 600 of each of the first sub package SPa and the second sub package SPb may not be covered with the package molding layer 900 but be exposed.

FIG. 2A is a cross-sectional view of a PiP-type semiconductor package according to embodiments. FIG. 2B is an enlarged view of a region IIB in FIG. 2A.

Referring to FIG. 2A, a package redistribution layer 500 may be formed on the bottom surface of the package substrate 600 and the bottom surface of the package molding layer 900, which are exposed by removing the release film 10 (in FIG. 1C), and a plurality of package connection terminals 550 may be attached to the bottom surface of the package redistribution layer 500, so that a PiP-type semiconductor package 1 may be formed. After the resultant structure of FIG. 1D is turned upside down such that the bottom surface of the package substrate 600 faces upwards, the package redistribution layer 500 may be formed on the package substrate 600 and the package molding layer 900 and the package connection terminals 550 may be attached to the package redistribution layer 500. Thereafter, the resultant structure having the package redistribution layer 500 and the package connection terminals 550 formed on the package substrate 600 and the package molding layer 900 may be turned upside down such that the package redistribution layer 500 and the package connection terminals 550 face downwards, so that the PiP-type semiconductor package 1 may be formed.

The package redistribution layer 500 may include a package redistribution insulating layer 510 and a plurality of package redistribution patterns 520. The package redistribution insulating layer 510 may surround the package redistribution patterns 520. In some embodiments, the package redistribution layer 500 may include a plurality of package redistribution insulating layers 510 stacked on each other. The package redistribution insulating layer 510 may include organic material. For example, the package redistribution insulating layer 510 may be formed from a photo-imageable dielectric (PID) or photosensitive polyimide (PSPI) or may be formed as an Ajinomoto build-up film (ABF). For example, the package redistribution layer 500 may have a thickness of about 20 μm to about 40 μm.

The package redistribution patterns 520 may include a plurality of package redistribution line patterns 522, a plurality of package redistribution vias 524, and a plurality of package redistribution seed layers 526. For example, the package redistribution patterns 520 may include, but not limited to, metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof. In some embodiments, the package redistribution line patterns 522 may include the same material as the package redistribution vias 524 and the package redistribution seed layers 526 may include a different material than the package redistribution line patterns 522 and the package redistribution vias 524. In some embodiments, the package redistribution line patterns 522 and the package redistribution vias 524 may include copper. For example, the package redistribution line patterns 522 and the package redistribution vias 524 may include copper or a copper alloy. In some embodiments, the package redistribution seed layers 526 may include titanium. For example, the package redistribution seed layers 526 may include titanium or titanium nitride.

The package redistribution line patterns 522 may be on at least one of the top and bottom surfaces of the package redistribution insulating layer 510. For example, when the package redistribution layer 500 includes a plurality of package redistribution insulating layers 510 stacked on each other, the package redistribution line patterns 522 may be on the bottom surface of each of the package redistribution insulating layers 510.

The package redistribution vias 524 may pass through at least one package redistribution insulating layer 510 and may be respectively connected to some of the package redistribution line patterns 522. In some embodiments, each of the package redistribution vias 524 may have a tapered shape having a horizontal width increasing downwards. For example, the horizontal width of each of the package redistribution vias 524 may increase away from the first sub package SPa and the second sub package SPb.

In some embodiments, at least some of the package redistribution line patterns 522 may be respectively and integrally formed with some of the package redistribution vias 524. For example, a package redistribution line pattern 522 may be integrally formed together with a package redistribution via 524 in contact with the top surface of the package redistribution line pattern 522, that is, a package redistribution via 524 extending from the top surface of the package redistribution line pattern 522. For example, each of the package redistribution vias 524 may have a horizontal width decreasing away from the package redistribution line pattern 522 that is integral with each package redistribution via 524. Each of the package redistribution seed layers 526 may cover the package redistribution line pattern 522 and the package redistribution via 524, which form an integral body. For example, each package redistribution seed layer 526 may cover the top surface of the package redistribution line pattern 522 and the top and side surfaces of the package redistribution via 524, wherein the package redistribution line pattern 522 and the package redistribution via 524 form an integral body. The package redistribution seed layer 526 may not cover the side and bottom surfaces of the package redistribution line pattern 522.

The package connection terminals 550 may be respectively attached to the bottom surfaces of at least some package redistribution line patterns 522 at the bottom among the package redistribution line patterns 522. For example, at least a portion of the bottom surface of each of the at least some package redistribution line patterns 522 at the bottom among the package redistribution line patterns 522 may not be covered with the package redistribution insulating layer 510 and may have attached thereto one of the package connection terminals 550.

Each of the package connection terminals 550 may include an under bump metallization (UBM) layer 552 and a conductive cap 554 attached to the UBM layer 552. The UBM layer 552 may be in contact with the package redistribution insulating layer 510 and one package redistribution line pattern 522, and the conductive cap 554 may be in contact with the UBM layer 552 but may not be in contact with the package redistribution line pattern 522. In some embodiments, the UBM layer 552 may include Ti, Cu, Ni, Au, NiV, NiP, TiNi, TiW, TaN, Al, Pd, CrCu, or a combination thereof. For example, the UBM layer 552 may include a stack structure of Cr/Cu/Au, a stack structure of Cr/CrCu/Cu, a TiWCu compound, a stack structure of TiWCu/Cu, a stack structure of Ni/Cu, a stack structure of NiV/Cu, a stack structure of Ti/Ni, a stack structure of Ti/NiP, a TiWNiV compound, a stack structure of Al/Ni/Au, a stack structure of Al/NiP/Au, a stack structure of Ti/TiNi/CuNi compounds, a stack structure of Ti/Ni/Pd, a stack structure of Ni/Pd/Au, or a stack structure of NiP/Pd/Au. The conductive cap 554 may include a solder ball or a solder bump.

In some embodiments, the package redistribution insulating layer 510 may partially fill the package cavity CVT (in FIG. 2B). For example, each of package redistribution vias 524 at the top among the package redistribution vias 524 may extend into the package cavity CVT to be in contact with a package lower pad LPD (in FIG. 2B) among the bottom conductive patterns 634. The package redistribution insulating layer 510 may surround at least a portion of each top package redistribution via 524 in the package cavity CVT and fill the package cavity CVT.

In some embodiments, the package redistribution insulating layer 510 may cover a lower side surface of the package substrate 600 of each of the first sub package SPa and the second sub package SPb. For example, the lower side surface of the package substrate 600 of each of the first sub package SPa and the second sub package SPb may be covered with the package redistribution insulating layer 510 and the upper side surface, e.g., the other side surface, of the package substrate 600 may be covered with the package molding layer 900.

At least some of the package connection terminals 550 may be attached to the bottom surface of the package redistribution layer 500 to be closer to the edge of the package redistribution layer 500 than to the first sub package SPa and the second sub package SPb. For example, the PiP-type semiconductor package 1 may correspond to a fan-out package, in which the package connection terminals 550 are arranged in a fan-out manner such that the footprint of the package connection terminals 550 is greater than the footprint of the first sub package SPa and the second sub package SPb according to a top view.

Referring to FIGS. 2A and 2B, the package cavity CVT may be between the bottommost end of the bottom solder resist layer 644 and the bottom surface of a bottom conductive pattern 634 and defined by the bottom solder resist layer 644. The package redistribution insulating layer 510 may fill a portion of the package cavity CVT. For example, each of package redistribution vias 524 at the top among the package redistribution vias 524 may extend into the package cavity CVT to be connected to a package lower pad LPD among the bottom conductive patterns 634. The package redistribution insulating layer 510 may surround at least a portion of each top package redistribution via 524 in the package cavity CVT and fill the package cavity CVT.

The bottom conductive pattern 634 may have a first thickness T1. The package redistribution line pattern 522 may have a second thickness T2. The first thickness T1 may be greater than the second thickness T2. The package lower pad LPD may have a first width W1, the package redistribution via 524 may have a second width W2, and the via pattern 620 may have a third width W3. The third width W3 may be greater than the second width W2. The first width W1 may be greater than the second width W2. In some embodiments, the first width W1 may be greater than the third width W3. Because the first width W1 is greater than the second width W2, the package redistribution via 524 and the package redistribution seed layer 526 covering the top surfaces of the package redistribution via 524 may be in contact with a portion of the package lower pad LPD and the package redistribution insulating layer 510 may be in contact with the other portion of the package lower pad LPD.

The package redistribution seed layer 526 may be between the package lower pad LPD and the package redistribution via 524. The package redistribution seed layer 526 may include a different material than each of the package redistribution line pattern 522 and the package redistribution via 524. The package redistribution seed layer 526 may include a different material than the bottom conductive pattern 634. In some embodiments, the package redistribution line pattern 522 and the package redistribution via 524 may include copper, the package redistribution seed layer 526 may include titanium, and the bottom conductive pattern 634 may include copper. The package cavity CVT may be completely filled with the package redistribution insulating layer 510, at least a portion of the package redistribution via 524, and a portion of the package redistribution seed layer 526 covering the top and side surfaces of the package redistribution via 524.

In the PiP-type semiconductor package 1 according to inventive concepts, an electronic component including the first sub package SPa and the second sub package SPb may be attached to not a printed circuit board (PCB) but the package redistribution layer 500 to implement a fan-out PiP. The package redistribution layer 500 may be formed thinner than a PCB. The package substrate 600 and the package redistribution layer 500, which are included in each of the first sub package SPa and the second sub package SPb, may be electrically connected to each other such that a wiring pattern 630 of the package substrate 600 is in direct contact with a package redistribution pattern 520 of the package redistribution layer 500 without a connection terminal, such as a solder ball, between the wiring pattern 630 and the package redistribution pattern 520, and accordingly, the reliability of electrical connection between the package substrate 600 and the package redistribution layer 500 may increase. Accordingly, the PiP-type semiconductor package 1 may be miniaturized because the overall thickness of the PiP-type semiconductor package 1 is reduced, and the electrical reliability of the PiP-type semiconductor package 1 may increase.

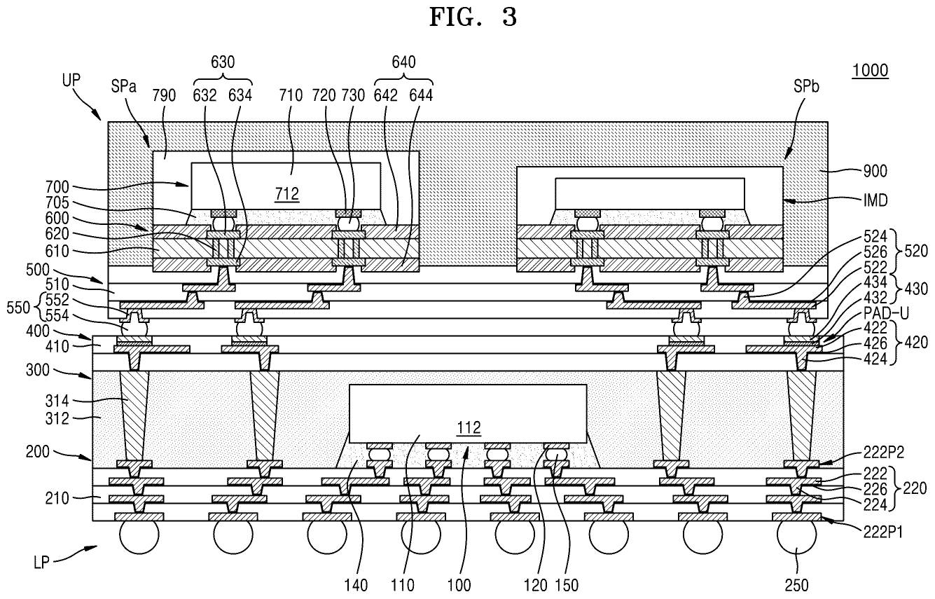

FIG. 3 is a cross-sectional view of a package-on-package (PoP)-type semiconductor package according to embodiments.

Referring to FIG. 3, a semiconductor package 1000 may be of a PoP type in which an upper package UP is attached to a lower package LP. The upper package UP may correspond to the PiP-type semiconductor package 1 of FIGS. 2A and 2B.

The lower package LP may include a first wiring structure 200, a second wiring structure 400 on the first wiring structure 200, at least one lower semiconductor chip 100 between the first wiring structure 200 and the second wiring structure 400, and an expansion layer 300, which is between the first wiring structure 200 and the second wiring structure 400 and surrounds the lower semiconductor chip 100. The expansion layer 300 may electrically connect the first wiring structure 200 to the second wiring structure 400. In some embodiments, the lower package LP may correspond to a fan-out-type wafer-level package (FOWLP). In some embodiments, the lower package LP may correspond to a fan-out-type panel-level package (FOPLP).

In some embodiments, at least one of the first wiring structure 200 and the second wiring structure 400 may be formed by a redistribution process. The first wiring structure 200 and the second wiring structure 400 may be respectively referred to as a first redistribution structure and a second redistribution structure or a lower redistribution structure and an upper redistribution structure. In some embodiments, the lower package LP may be formed by a chip-last method, in which the first wiring structure 200 is formed and then the lower semiconductor chip 100 and the expansion layer 300 are formed on the first wiring structure 200. In some embodiments, at least one of the first wiring structure 200 and the second wiring structure 400 may correspond to a PCB that is similar to the package substrate 600 described above with reference to FIGS. 1A to 2B.

The first wiring structure 200 may include a first redistribution insulating layer 210 and a plurality of first redistribution patterns 220. The first redistribution patterns 220 may include a plurality of first redistribution line patterns 222, a plurality of first redistribution vias 224, and a plurality of first redistribution seed layers 226. The first redistribution insulating layer 210 and the first redistribution patterns 220 of the first wiring structure 200 are substantially and respectively similar to the package redistribution insulating layer 510 and the package redistribution patterns 520 of the package redistribution layer 500, and thus, redundant descriptions thereof may be omitted.

The first redistribution vias 224 may pass through at least one first redistribution insulating layer 210 and may be respectively in contact with and connected to some of the first redistribution line patterns 222. In some embodiments, each of the first redistribution vias 224 may have a tapered shape having a horizontal width increasing upwards. For example, the horizontal width of each first redistribution via 224 may increase toward the lower semiconductor chip 100.

In some embodiments, at least some of the first redistribution line patterns 222 may be respectively and integrally formed with some of the first redistribution vias 224. For example, a first redistribution line pattern 222 may be integrally formed together with a first redistribution via 224 in contact with the bottom surface of the first redistribution line pattern 222, that is, a first redistribution via 224 extending from the bottom surface of the first redistribution line pattern 222. For example, each of the first redistribution vias 224 may have a horizontal width decreasing away from the first redistribution line pattern 222 that is integral with each first redistribution via 224. Each of the first redistribution seed layers 226 may cover the first redistribution line pattern 222 and the first redistribution via 224, which form an integral body. For example, each first redistribution seed layer 226 may cover the bottom surface of the first redistribution line pattern 222 and the bottom and side surfaces of the first redistribution via 224, wherein the first redistribution line pattern 222 and the first redistribution via 224 form an integral body. The first redistribution seed layer 226 may not cover the side and top surfaces of the first redistribution line pattern 222.

In some embodiments, the bottom surface of the bottommost first redistribution insulating layer 210 and the bottommost surfaces of the first redistribution patterns 220, e.g., the bottom surfaces of the bottommost first redistribution line patterns 222, may be at the same vertical level and coplanar with each other.

The first wiring structure 200 may include a plurality of bottom connection pads 222P1 on the bottom surface of the first wiring structure 200 and a plurality of expansion connection pads 222P2 on the top surface of the first wiring structure 200. In some embodiments, the bottom connection pads 222P1 and the expansion connection pads 222P2 may correspond to some of the first redistribution line patterns 222. A plurality of external connection terminals 250 may be respectively attached to the bottom connection pads 222P1. The external connection terminals 250 may connect the semiconductor package 1000 to the outside. A plurality of connection structures 314 may be respectively attached to some of the expansion connection pads 222P2 and a plurality of lower chip connectors 150 may be respectively attached to the other expansion connection pads 222P2. The lower chip connectors 150 may be between a plurality of lower chip pads 120 and the other expansion connection pads 222P2 and may electrically connect the lower semiconductor chip 100 to the first wiring structure 200. In some embodiments, a lower underfill layer 140 surrounding the lower chip connectors 150 may be between the lower semiconductor chip 100 and the first wiring structure 200. For example, the lower underfill layer 140 may include epoxy resin formed using a capillary underfill process. In some embodiments, the lower underfill layer 140 may include an NCF.

The lower semiconductor chip 100 may be attached to the first wiring structure 200. The lower semiconductor chip 100 may include a lower semiconductor substrate 110 having an active surface and an inactive surface opposite to the active surface, a lower semiconductor device 112 on the active surface of the lower semiconductor substrate 110, and the lower chip pads 120 disposed on the lower semiconductor device 112. The lower semiconductor chip 100 may have a first surface and a second surface opposite to the first surface. The lower chip pads 120 may be disposed on the first surface of the lower semiconductor chip 100. The second surface of the lower semiconductor chip 100 may correspond to the inactive surface of the lower semiconductor substrate 110. The active surface of the lower semiconductor substrate 110 is very close to the first surface of the lower semiconductor chip 100 and thus not separately illustrated from the first surface of the lower semiconductor chip 100 in the drawings. The lower semiconductor chip 100, the lower semiconductor substrate 110, and the lower chip pads 120 are substantially and respectively similar to the semiconductor chip 700, the semiconductor substrate 710, and the chip pads 720, and thus, redundant descriptions thereof may be omitted.

In some embodiments, the lower semiconductor chip 100 may be attached to the top surface of the first wiring structure 200 in a face-down manner such that the first surface of the lower semiconductor chip 100 faces the first wiring structure 200. For example, the lower semiconductor chip 100 may be arranged on the first wiring structure 200 such that the lower chip pads 120 face the first wiring structure 200. In this case, the first surface of the lower semiconductor chip 100 may be referred to as the bottom surface of the lower semiconductor chip 100 and the second surface of the lower semiconductor chip 100 may be referred to as the top surface of the lower semiconductor chip 100.

The expansion layer 300 may include an encapsulation material 312 and the connection structures 314. The connection structures 314 may pass through the encapsulation material 312 and electrically connect the first wiring structure 200 to the second wiring structure 400. The connection structures 314 may include a through mold via (TMV), a conductive post, a conductive pillar, or at least one conductive bump. The encapsulation material 312 may surround the lower semiconductor chip 100 and the connection structures 314 and fill between the first wiring structure 200 and the second wiring structure 400. For example, the encapsulation material 312 may include an EMC.

The second wiring structure 400 may include a second redistribution insulating layer 410 and a plurality of second redistribution patterns 420. The second redistribution patterns 420 may include a plurality of second redistribution line patterns 422, a plurality of second redistribution vias 424, and a plurality of second redistribution seed layers 426. The second redistribution insulating layer 410 and the second redistribution patterns 420 of the second wiring structure 400 are substantially and respectively similar to the first redistribution insulating layer 210 and the first redistribution patterns 220 of the first wiring structure 200, and thus, redundant descriptions thereof may be omitted.

In some embodiments, the second wiring structure 400 may be thinner than the first wiring structure 200. For example, the first wiring structure 200 may have a thickness of about 30 μm to about 50 μm and the second wiring structure 400 may have a thickness of about 20 μm to about 40 μm that is less than the thickness of the first wiring structure 200. In some embodiments, the second wiring structure 400 may include a plurality of second redistribution insulating layers 410 stacked on each other. For example, the number of second redistribution insulating layers 410 stacked in the second wiring structure 400 may be less than the number of first redistribution insulating layers 210 stacked in the first wiring structure 200.

The second redistribution vias 424 may pass through at least one second redistribution insulating layer 410 and may be respectively in contact with and connected to some of the second redistribution line patterns 422. In some embodiments, each of the second redistribution vias 424 may have a tapered shape having a horizontal width increasing upwards. For example, the horizontal width of each of the second redistribution vias 424 may increase away from the lower semiconductor chip 100. Each of some second redistribution vias 424 at the bottom among the plurality of second redistribution vias 424 may be connected to the top surface of one of the connection structures 314.

In some embodiments, at least some of the second redistribution line patterns 422 may be respectively and integrally formed with some of the second redistribution vias 424. For example, a second redistribution line pattern 422 may be integrally formed together with a second redistribution via 424 in contact with the bottom surface of the second redistribution line pattern 422, that is, a second redistribution via 424 extending from the bottom surface of the second redistribution line pattern 422. For example, each of the second redistribution vias 424 may have a horizontal width decreasing away from the second redistribution line pattern 422 that is integral with each second redistribution via 424.

The second wiring structure 400 may include a plurality of upper connection pads PAD-U on the top surface thereof. In some embodiments, each of the upper connection pads PAD-U may include an upper connection pad layer 430, which covers the top surface of a portion of the second redistribution line pattern 422. The upper connection pad layer 430 may include a first upper metal layer 432 and a second upper metal layer 434, which are sequentially stacked on the second redistribution line pattern 422. In some embodiments, the first upper metal layer 432 may include nickel (Ni) and the second upper metal layer 434 may include gold (Au). However, embodiments are not limited thereto.

The upper package UP may be attached to the second wiring structure 400. For example, the upper package UP may be connected to the upper connection pads PAD-U. For example, the package connection terminals 550 may be between the upper package UP and the upper connection pads PAD-U. For example, the conductive caps 554 of the respective package connection terminals 550 may be respectively attached to a plurality of upper connection pad layers 430. The package connection terminals 550 may electrically connect the lower package LP to the upper package UP.

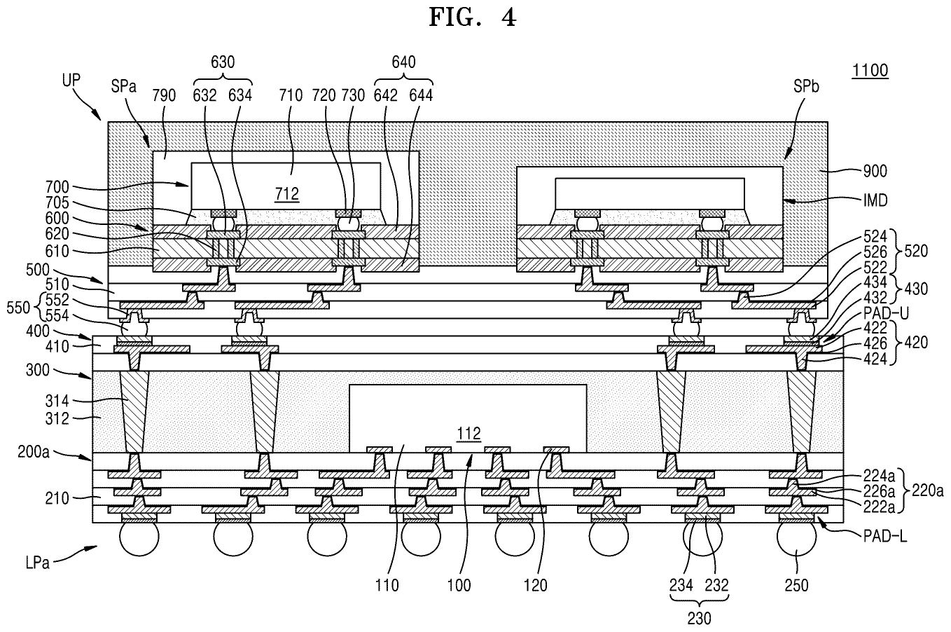

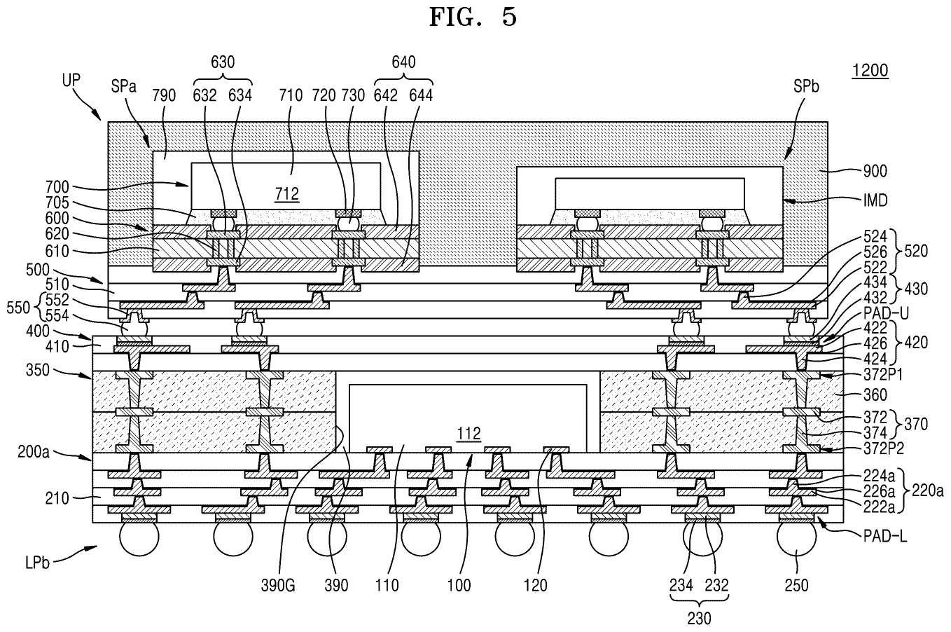

FIG. 4 is a cross-sectional view of a PoP-type semiconductor package according to embodiments.

Referring to FIG. 4, a semiconductor package 1100 may be of a PoP type in which the upper package UP is attached to a lower package LPa. The lower package LPa of the semiconductor package 1100 may include a first wiring structure 200a instead of the first wiring structure 200 included in the lower package LP of the semiconductor package 1000 of FIG. 3. In some embodiments, the lower package LPa may correspond to an FOWLP.

The first wiring structure 200a may include a first redistribution insulating layer 210 and a plurality of first redistribution patterns 220a. The first redistribution patterns 220a may include a plurality of first redistribution line patterns 222a, a plurality of first redistribution vias 224a, and a plurality of first redistribution seed layers 226a. The first redistribution insulating layer 210 and the first redistribution patterns 220a of the first wiring structure 200a are substantially and respectively similar to the first redistribution insulating layer 210 and the first redistribution patterns 220 of the first wiring structure 200, and thus, redundant descriptions thereof may be omitted.

The first redistribution vias 224a may pass through at least one first redistribution insulating layer 210 and may be respectively in contact with and connected to some of the first redistribution line patterns 222a. In some embodiments, each of the first redistribution vias 224a may have a tapered shape having a horizontal width increasing downwards. For example, the horizontal width of each first redistribution via 224a may increase away from the lower semiconductor chip 100.

In some embodiments, at least some of the first redistribution line patterns 222a may be respectively and integrally formed with some of the first redistribution vias 224a. For example, a first redistribution line pattern 222a may be integrally formed together with a first redistribution via 224a in contact with the top surface of the first redistribution line pattern 222a, that is, a first redistribution via 224a extending from the top surface of the first redistribution line pattern 222a. For example, each of the first redistribution vias 224a may have a horizontal width decreasing away from the first redistribution line pattern 222a that is integral with each first redistribution via 224a. Each of the first redistribution seed layers 226a may cover the first redistribution line pattern 222a and the first redistribution via 224a, which form an integral body. For example, each first redistribution seed layer 226a may cover the top surface of the first redistribution line pattern 222a and the top and side surfaces of the first redistribution via 224a, wherein the first redistribution line pattern 222a and the first redistribution via 224a form an integral body. The first redistribution seed layer 226a may not cover the side and bottom surfaces of the first redistribution line pattern 222a.

The lower chip pads 120 may be respectively in contact with and connected to some of first redistribution vias 224a at the top among the first redistribution vias 224a. The connection structures 314 may be respectively in contact with and connected to the other first redistribution vias 224a at the top among the first redistribution vias 224a. In some embodiments, the bottom surface of the lower semiconductor chip 100, the bottom surface of the encapsulation material 312, and the bottom surface of each of the connection structures 314 may be at the same vertical level and coplanar with one another. In some embodiments, the lower package LPa may be formed by a chip-first method, in which the expansion layer 300 and the lower semiconductor chip 100 are formed first and then the first wiring structure 200a is formed. In some embodiments, the top surface of the topmost first redistribution insulating layer 210 and the topmost surfaces of the first redistribution patterns 220a, e.g., the top surfaces of the topmost first redistribution vias 224a, may be at the same vertical level and coplanar with each other.

The first wiring structure 200a may include a plurality of lower connection pads PAD-L on the bottom surface of the first wiring structure 200a. In some embodiments, each of the lower connection pads PAD-L may include a lower connection pad layer 230, which covers the bottom surface of a portion of the first redistribution line pattern 222a. The lower connection pad layer 230 may include a first lower metal layer 232 and a second lower metal layer 234, which are sequentially stacked on the first redistribution line pattern 222a. In some embodiments, the first lower metal layer 232 may include nickel (Ni) and the second lower metal layer 234 may include gold (Au). However, embodiments are not limited thereto. The external connection terminals 250 may be respectively attached to the lower connection pads PAD-L. The external connection terminals 250 may connect the semiconductor package 1100 to the outside.

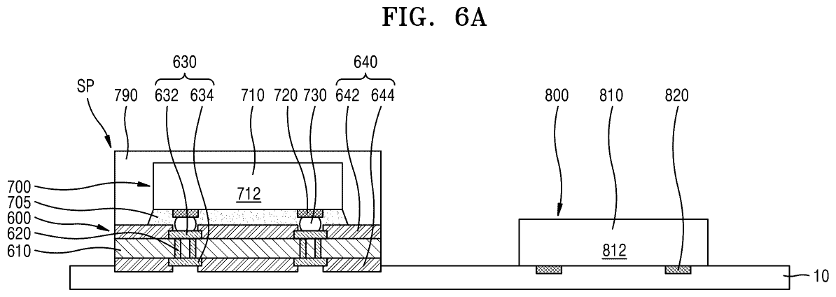

FIG. 5 is a cross-sectional view of a PoP-type semiconductor package according to embodiments.

Referring to FIG. 5, a semiconductor package 1200 may be of a PoP type in which the upper package UP is attached to a lower package LPb. The lower package LPb of the semiconductor package 1200 may include an expansion layer 350 instead of the expansion layer 300 included in the lower package LPa of the semiconductor package 1100 of FIG. 4. In some embodiments, the lower package LPb may correspond to an FOPLP.

The expansion layer 350 may electrically connect the first wiring structure 200a to the second wiring structure 400. The expansion layer 350 may have a mounting space 390G, in which the lower semiconductor chip 100 is arranged. The expansion layer 350 may include an expansion base layer 360 and a plurality of via structures 370. The via structures 370 may penetrate from the top to the bottom of the expansion base layer 360. The expansion layer 350 may include a PCB, a ceramic substrate, a wafer for package manufacturing, or an interposer. The expansion layer 350 may include one expansion base layer 360. In some embodiments, the expansion layer 350 may include at least two expansion base layers 360 stacked on each other. For example, the expansion layer 350 may include a multi-layer PCB.

The mounting space 390G may be formed as an opening or a cavity in the expansion layer 350. The mounting space 390G may be in a partial region of the expansion layer 350, e.g., a central region of the expansion layer 350 according to a top view. The mounting space 390G may be recessed to a certain depth from the top surface of the expansion layer 350 or may penetrate from the top to the bottom of the expansion layer 350. To form the mounting space 390G, dry etching, wet etching, screen printing, a drill bit, or a laser drilling process may be used.

The expansion base layer 360 may include at least one material selected from the group consisting of phenol resin, epoxy resin, and polyimide. For example, the expansion base layer 360 may include at least one material selected from the group consisting of FR-4, tetrafunctional epoxy, polyphenylene ether, epoxy/polyphenylene oxide, BT, thermount, cyanate ester, polyimide, and liquid crystal polymer. Each of the via structures 370 may include a via connection pattern portion 372 and an expansion via portion 374. The via connection pattern portion 372 may be in the top or bottom surface of the expansion base layer 360. For example, when the expansion layer 350 includes a plurality of expansion base layers 360 stacked on each other, the via connection pattern portion 372 may be arranged on at least some of the top surface of the topmost expansion base layer 360, the bottom surface of the bottommost expansion base layer 360, and between two adjacent expansion base layers 360. The expansion via portion 374 may pass through the expansion base layer 360 and extend in the vertical direction. The expansion via portion 374 may connect two via connection pattern portions 372 at different vertical levels. In some embodiments, the via connection pattern portion 372 may include ED copper foil, RA copper foil, stainless steel foil, aluminum foil, ultra-thin copper foil, sputtered copper, or a copper alloy. In some embodiments, the expansion via portion 374 may include copper (Cu) or an alloy including Cu. For example, the expansion via portion 374 may include, but not limited to, Cu, Ti, TiW, TiN, Ta, TaN, Cr, a Cu/Ti structure, in which Cu is stacked on Ti, or a structure, in which Cu or an alloy including Cu is stacked on a seed layer including a Cu/TiW structure in which Cu is stacked on TiW.

In some embodiments, the bottom surface of the expansion base layer 360 and the bottommost surface of each of the via structures 370 may be at the same vertical level and coplanar with each other. For example, when the expansion layer 350 includes a plurality of expansion base layers 360 stacked on each other, the bottom surface of a bottommost expansion base layer 360 and the bottommost surface of each of the via structures 370 may be at the same vertical level and coplanar with each other. For example, the bottom surface of the bottommost expansion base layer 360, the bottommost surface of each of the via structures 370, the top surface of a topmost first redistribution insulating layer 210, and the top surface of a topmost first redistribution via 224a may be at the same vertical level.

Among a plurality of via connection pattern portions 372 of the respective via structures 370, a bottommost via connection pattern portion 372 may be referred to as a upper expansion connection pad 372P1 and a topmost via connection pattern portion 372 may be referred to as an bottom expansion connection pad 372P2. In some embodiments, the bottom surface of the bottommost expansion base layer 360 and the bottom surface of the bottom expansion connection pad 372P2 may be at the same vertical level and coplanar with each other. For example, the bottom surface of the bottommost expansion base layer 360, the bottom surface of the bottom expansion connection pad 372P2, the top surface of the topmost first redistribution insulating layer 210, and the top surface of the topmost first redistribution via 224a may be at the same vertical level.

The semiconductor package 1200 may further include a filling insulation layer 390 filling the mounting space 390G. The filling insulation layer 390 may fill the space between the expansion base layer 360 and the lower semiconductor chip 100 arranged in the mounting space 390G. For example, the filling insulation layer 390 may include thermosetting resin such as epoxy resin, thermoplastic resin such as polyimide, or resin, such as an ABF, FR-4, or BT, which includes a reinforcing material such as an inorganic filler. The filling insulation layer 390 may be formed from a molding material, such as an EMC, or a photosensitive material, such as a photo-imageable encapsulant (PIE). In some embodiments, a portion of the filling insulation layer 390 may include an insulating material, such as a silicon oxide film, a silicon nitride film, or a silicon oxynitride film.

In some embodiments, the bottom surface of the lower semiconductor chip 100, the bottom surface of the expansion base layer 360, and the bottom surface of the filling insulation layer 390 may be at the same vertical level and coplanar with one another. In some embodiments, the lower package LPb may be formed by a chip-first method, in which the expansion layer 350, the lower semiconductor chip 100, and the filling insulation layer 390 are formed first and then the first wiring structure 200a is formed. For example, the top surface of the topmost first redistribution insulating layer 210, the top surface of the topmost first redistribution via 224a, the bottom surface of each of the lower chip pads 120, the bottommost surface of each of the via structures 370, the bottom surface of the expansion base layer 360, and the bottom surface of the filling insulation layer 390 may be at the same vertical level.

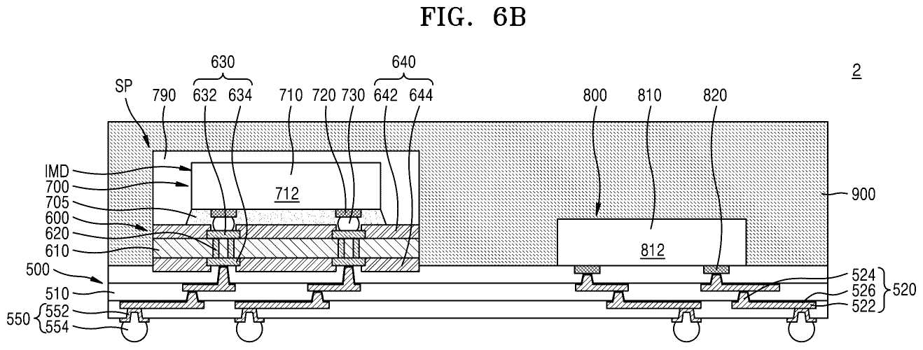

FIG. 6A is a cross-sectional view illustrating a method of manufacturing a PiP-type semiconductor package, according to embodiments. FIG. 6B is a cross-sectional view of a PiP-type semiconductor package according to embodiments.

Referring to FIG. 6A, a plurality of electronic components including a sub package SP and an electronic device 800 may be prepared and attached to a release film 10. The sub package SP may include a package substrate 600, at least one semiconductor chip 700 attached to the package substrate 600, and a sub molding layer 790 formed on the package substrate 600 to cover the semiconductor chip 700. The sub package SP is substantially similar to the first sub package SPa in FIG. 1A, and thus, redundant descriptions thereof may be omitted. The electronic device 800 may correspond to a semiconductor chip, e.g., a die that has not undergone a packaging process. The electronic device 800 may include a component substrate 810 having an active surface and an inactive surface opposite to the active surface, a component device 812 formed on the active surface of the component substrate 810, and a plurality of component pads 820 disposed on the component device 812. The electronic device 800 may have a first surface and a second surface opposite to the first surface. The component pads 820 may be arranged on the first surface of the electronic device 800. The second surface of the electronic device 800 may correspond to the inactive surface of the component substrate 810. The active surface of the component substrate 810 is very close to the first surface of the electronic device 800 and thus not separately illustrated from the first surface of the electronic device 800 in the drawings. The electronic device 800, the component substrate 810, and the component pads 820 are substantially and respectively similar to the semiconductor chip 700, the semiconductor substrate 710, and the chip pads 720, and thus, redundant descriptions thereof may be omitted.

In some embodiments, the electronic device 800 may include a power device. For example, the electronic device 800 may include, but not limited to, a power management integrated circuit (PMIC). For example, the electronic device 800 may correspond to a semiconductor chip or a die each including any type of semiconductor device, in which a packaging process has not performed on the component substrate 810 and the component device 812.

Each of the component pads 820 may be formed on the bottom surface of the component substrate 810 to protrude downwards from the bottom surface of the component substrate 810. In some embodiments, the release film 10 may be in contact with the bottom surface of the component substrate 810 but may not cover the side surface of the component substrate 810. For example, the top surface of the release film 10 and the bottom surface of the component substrate 810 may be at the same vertical level. The component pads 820 may be embedded in the release film 10. For example, the release film 10 may cover the bottom and side surfaces of each of the component pads 820.

Referring to FIGS. 6A and 6B, a PiP-type semiconductor package 2 may be formed by forming the package molding layer 900, removing the release film 10, forming the package redistribution layer 500, and attaching the package connection terminals 550 to the bottom surface of the package redistribution layer 500, as shown in FIGS. 1C, 1D, and 2A.

The PiP-type semiconductor package 2 may include the package redistribution layer 500, a plurality of electronic components which are arranged on the package redistribution layer 500 to be apart from each other in a horizontal direction and include the sub package SP and the electronic device 800, the package molding layer 900 covering the top surface of the package redistribution layer 500 and surrounding the electronic components, and the package connection terminals 550 attached to the bottom surface of the package redistribution layer 500.

The package redistribution insulating layer 510 may cover the bottom and lower side surfaces of the package substrate 600 of the sub package SP. The package redistribution insulating layer 510 may cover the bottom and side surfaces of each of the component pads 820. The package redistribution insulating layer 510 may cover the bottom surface of the component substrate 810 but may not cover the side surface of the component substrate 810. The package molding layer 900 may entirely cover the side surface of the component substrate 810.

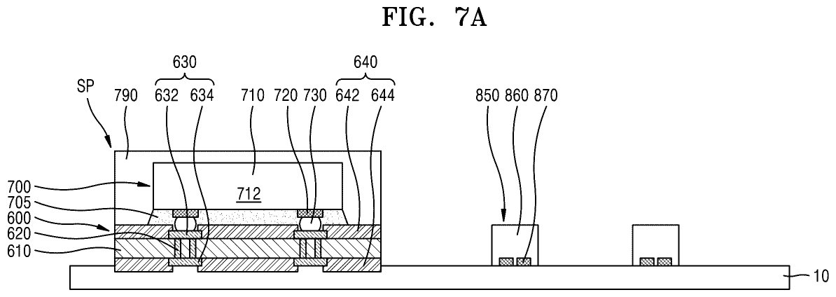

FIG. 7A is a cross-sectional view illustrating a method of manufacturing a PiP-type semiconductor package, according to embodiments. FIG. 7B is a cross-sectional view of a PiP-type semiconductor package according to embodiments.

Referring to FIG. 7A, a plurality of electronic components including the sub package SP and an electronic device 850 may be prepared and attached to the release film 10. The sub package SP may include the package substrate 600, at least one semiconductor chip 700 attached to the package substrate 600, and the sub molding layer 790 formed on the package substrate 600 to cover the semiconductor chip 700. The electronic device 850 may include a component body 860 and a plurality of component pads 870 at the bottom of the component body 860. The component pads 870 may be formed at the bottom of the component body 860 to be embedded in the component body 860. For example, the bottom surface of the component body 860 and the bottom surface of each of the component pads 870 may be at the same vertical level. In some embodiments, the release film 10 may be in contact with the bottom surface of the component body 860 and the bottom surface of each of the component pads 870 but may not cover the side surface of each of the component body 860 and the component pads 870. For example, the top surface of the release film 10, the bottom surface of the component body 860, and the bottom surfaces of the component pads 870 may be at the same vertical level.

In some embodiments, the electronic device 850 may correspond to a passive device. For example, the electronic device 850 may correspond to a multi-layer ceramic capacitor (MLCC) but is not limited thereto. For example, the electronic device 850 may correspond to any one of various types and shapes of passive devices, such as a resistor, a capacitor, and an inductor.

Referring to FIGS. 7A and 7B, a PiP-type semiconductor package 3 may be formed by forming the package molding layer 900, removing the release film 10, forming the package redistribution layer 500, and attaching the package connection terminals 550 to the bottom surface of the package redistribution layer 500, as shown in FIGS. 1C, 1D, and 2A.

The semiconductor package 3 may include the package redistribution layer 500, a plurality of electronic components which are arranged on the package redistribution layer 500 to be apart from each other in a horizontal direction and include the sub package SP and the electronic device 850, the package molding layer 900 covering the top surface of the package redistribution layer 500 and surrounding the electronic components, and the package connection terminals 550 attached to the bottom surface of the package redistribution layer 500.

The package redistribution insulating layer 510 may cover the bottom and lower side surfaces of the package substrate 600 of the sub package SP. The package redistribution insulating layer 510 may cover the bottom surface of the component body 860 and the bottom surface of each of the component pads 870 but may not cover the side surface of each of the component body 860 and the component pads 870. The package molding layer 900 may entirely cover the side surface of the component body 860. For example, the top surface of the package redistribution insulating layer 510, the bottom surface of the component body 860, and the bottom surface of the component pads 870 may be at the same vertical level.

Although it has been described that the electronic device 800 in FIGS. 6A and 6B corresponds to a die including a semiconductor device and the electronic device 850 in FIGS. 7A and 7B corresponds to a passive device, embodiments are not limited thereto. For example, the electronic device 800 in FIGS. 6A and 6B may correspond to a die, which includes the protruding component pads 820 and a semiconductor device, or a passive device including the protruding component pads 820. For example, the electronic device 850 in FIGS. 7A and 7B may correspond to a die, which includes the embedded component pads 870 and a semiconductor device, or a passive device including the embedded component pads 870.

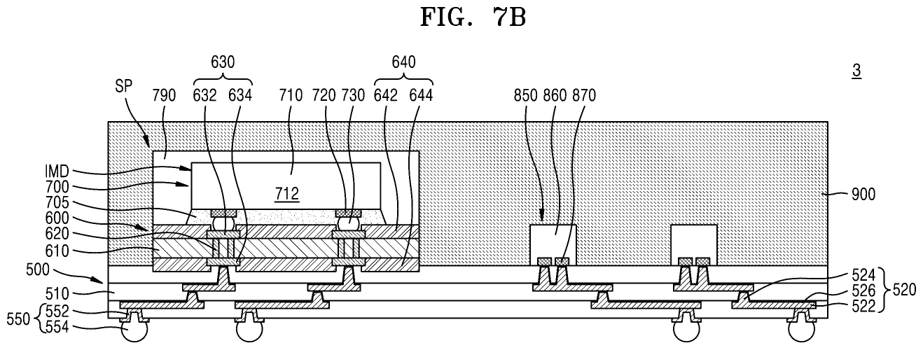

FIG. 8 is a cross-sectional view of a PiP-type semiconductor package according to embodiments.

Referring to FIG. 8, a PiP-type semiconductor package 4 may include the package redistribution layer 500, a plurality of electronic components which are arranged on the package redistribution layer 500 to be apart from each other in a horizontal direction and include the first sub package SPa and a second sub package SPc, the package molding layer 900 covering the top surface of the package redistribution layer 500 and surrounding the electronic components, and the package connection terminals 550 attached to the bottom surface of the package redistribution layer 500.

The second sub package SPc may include the package substrate 600, a plurality of semiconductor chips 750 sequentially stacked on the package substrate 600, and the sub molding layer 790 disposed on the package substrate 600 to cover the semiconductor chips 750.

Each of the semiconductor chips 750 may include a semiconductor substrate 760 having an active surface and an inactive surface opposite to the active surface, a semiconductor device 762 on the active surface of the semiconductor substrate 760, and a plurality of chip pads 770 in the semiconductor device 762. Each semiconductor chip 750 may have a first surface and a second surface opposite to the first surface. The chip pads 770 may be arranged in the first surface of the semiconductor chip 750. The second surface of the semiconductor chip 750 may correspond to the inactive surface of the semiconductor substrate 760. The active surface of the semiconductor substrate 760 is very close to the first surface of the semiconductor chip 750 and thus not separately illustrated from the first surface of the semiconductor chip 750 in the drawings.

The semiconductor chip 750 may be attached to the top surface of the package substrate 600 in a face-up manner such that the inactive surface of the semiconductor substrate 760 faces the package substrate 600. For example, the plurality of semiconductor chips 750 may be sequentially stacked on the package substrate 600 such that a die attach film (DAF) 755 is attached to the second surface of one of the semiconductor chips 750 and is arranged to be in contact with the top surface of the package substrate 600 below the DAF 755 or the first surface of another semiconductor chip 750 below the DAF 755. A plurality of chip connectors 780 may connect the chip pads 770 to package upper pads corresponding to at least some of the top conductive patterns 632. Each of the chip connectors 780 may correspond to a bonding wire.

To distinguish the semiconductor chip 700 of the first sub package SPa from the semiconductor chip 750 of the second sub package SPc, the semiconductor chip 700, the semiconductor substrate 710, the semiconductor device 712, the chip pad 720, and the chip connector 730 of the first sub package SPa may be respectively referred to as a first semiconductor chip, a first semiconductor substrate, a first semiconductor device, a first chip pad, and a first chip connector and the semiconductor chip 750, the semiconductor substrate 760, the semiconductor device 762, the chip pad 770, and the chip connector 780 of the second sub package SPc may be respectively referred to as a second semiconductor chip, a second semiconductor substrate, a second semiconductor device, a second chip pad, and a second chip connector. In some embodiments, the first semiconductor device may correspond to a logic device and the second semiconductor device may correspond to a memory device.

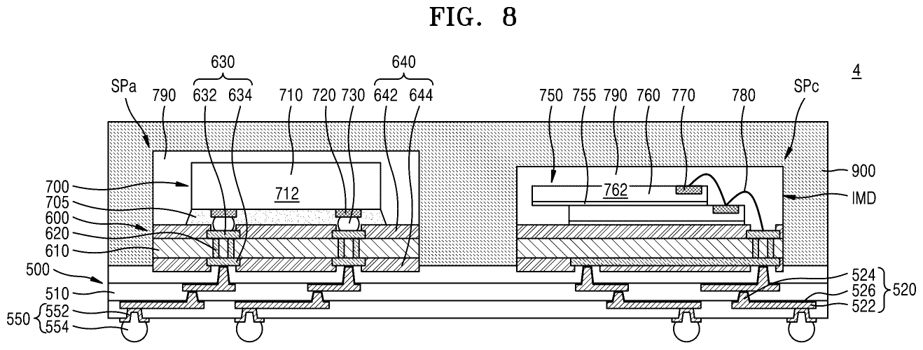

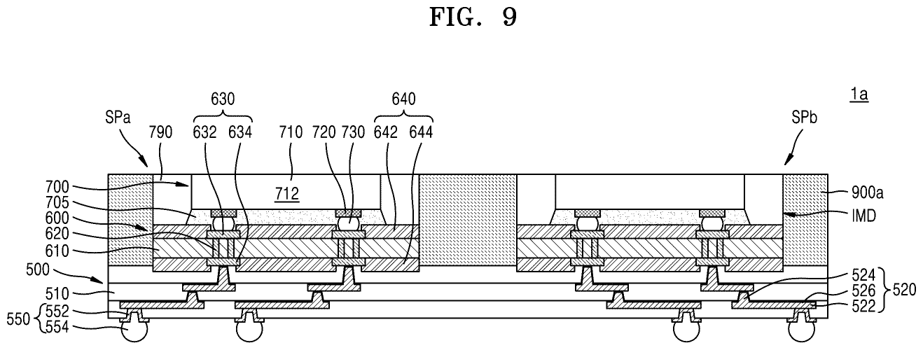

FIG. 9 is a cross-sectional view of a PiP-type semiconductor package according to embodiments.

Referring to FIG. 9, a PiP-type semiconductor package 1a may include the package redistribution layer 500, a plurality of electronic components which are arranged on the package redistribution layer 500 to be apart from each other in a horizontal direction and include the first sub package SPa and the second sub package SPb, a package molding layer 900a covering the top surface of the package redistribution layer 500 and surrounding the electronic components, and the package connection terminals 550 attached to the bottom surface of the package redistribution layer 500. The package molding layer 900a may entirely cover the side surface of each of the first sub package SPa and the second sub package SPb but may not cover the top surface of each of the first sub package SPa and the second sub package SPb. The top surface of the package molding layer 900a, the top surface of the first sub package SPa, and the top surface of the second sub package SPb may be at the same vertical level and coplanar with one another.

In some embodiments, the semiconductor package 1a may further include a heat dissipation unit, which covers the top surface of each of the first sub package SPa and the second sub package SPb. The heat dissipation unit may include a heat slug or a heat sink. The semiconductor package 1a may further include a thermal interface material (TIM) between the heat dissipation unit and the first sub package SPa and between the heat dissipation unit and the second sub package SPb. The TIM may be formed as paste or a film.

Each of the PiP-type semiconductor package 2 of FIG. 6B, the PiP-type semiconductor package 3 of FIG. 7B, the PiP-type semiconductor package 4 of FIG. 8, and the PiP-type semiconductor package 1a of FIG. 9 may be attached, as an upper package, to any one of the lower package LP in FIG. 3, the lower package LPa in FIG. 4, and the lower package LPb in FIG. 5, thereby forming a PoP-type semiconductor package.

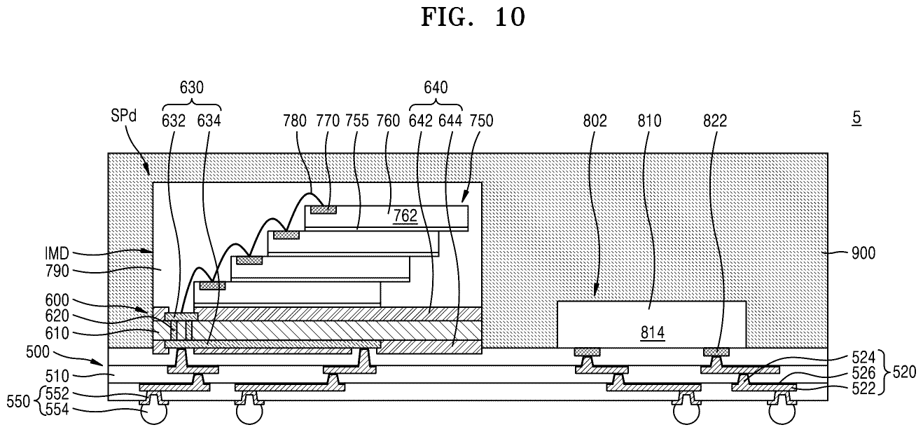

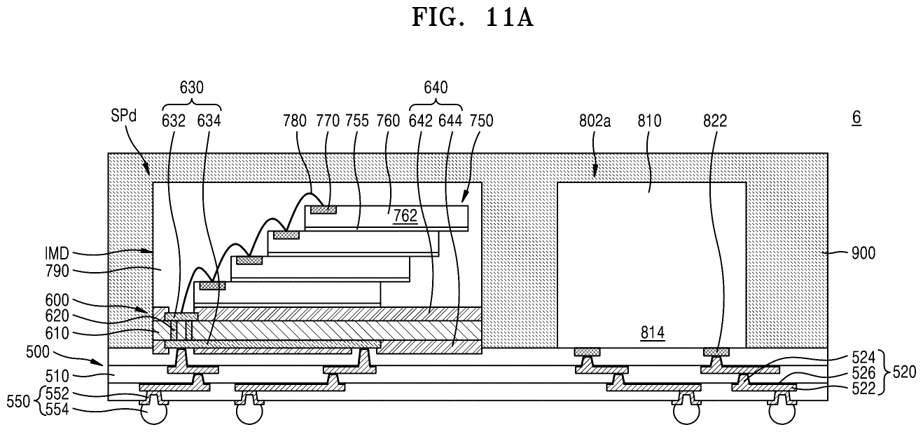

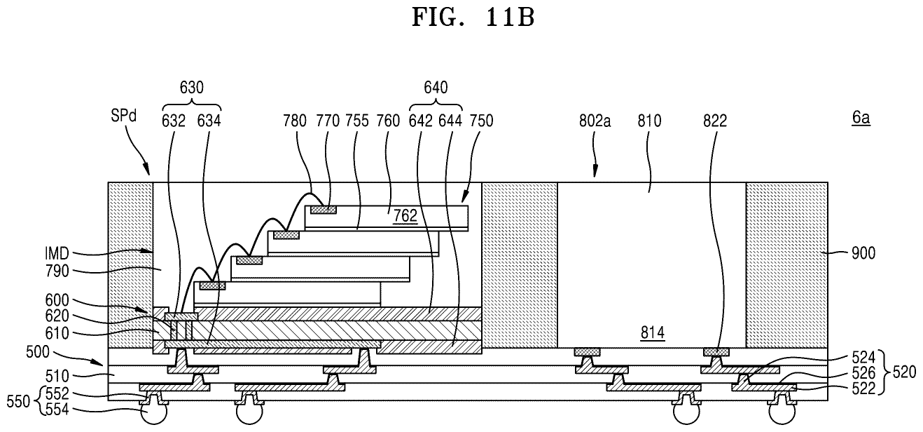

FIGS. 10, 11A, and 11B are cross-sectional views of PiP-type semiconductor packages according to embodiments.

Referring to FIG. 10, a PiP-type semiconductor package 5 may include the package redistribution layer 500, a plurality of electronic components which are arranged on the package redistribution layer 500 to be apart from each other in a horizontal direction and include a sub package SPd and an electronic device 802, the package molding layer 900 covering the top surface of the package redistribution layer 500 and surrounding the electronic components, and the package connection terminals 550 attached to the bottom surface of the package redistribution layer 500. The package molding layer 900 may entirely cover the side and top surfaces of each of the sub package SPd and the electronic device 802.

The electronic device 802 may correspond to a semiconductor chip, e.g., a die, which has not undergone a packaging process. The electronic device 802 may include the component substrate 810 having the active surface and the inactive surface opposite to the active surface, a component device 814 formed on the active surface of the component substrate 810, and a plurality of component pads 822 disposed on the component device 814. The electronic device 802 may have a first surface and a second surface opposite to the first surface. The component pads 822 may be arranged on the first surface of the electronic device 802. The second surface of the electronic device 802 may correspond to the inactive surface of the component substrate 810. The active surface of the component substrate 810 is very close to the first surface of the electronic device 802 and thus not separately illustrated from the first surface of the electronic device 802 in the drawings. The electronic device 802, the component substrate 810, and the component pads 822 are substantially and respectively similar to the semiconductor chip 700, the semiconductor substrate 710, and the chip pads 720, and thus, redundant descriptions thereof may be omitted.

In some embodiments, the electronic device 802 may include a logic device. For example, the electronic device 802 may include a CPU chip, a GPU chip, or an AP chip.

The sub package SPd may include the package substrate 600, the plurality of semiconductor chips 750 sequentially stacked on the package substrate 600, and the sub molding layer 790, which is on the package substrate 600 and covers the semiconductor chips 750.

Each of the semiconductor chips 750 may include a semiconductor substrate 760 having an active surface and an inactive surface opposite to the active surface, a semiconductor device 762 on the active surface of the semiconductor substrate 760, and a plurality of chip pads 770 in the semiconductor device 762. In some embodiments, the semiconductor device 762 may correspond to a memory device and each of the semiconductor chips 750 may correspond to a memory semiconductor chip. For example, the semiconductor device 762 may correspond to a non-volatile memory device including flash memory, PRAM, MRAM, FeRAM, or RRAM. For example, the flash memory may include NAND flash memory or VNAND flash memory.

Each semiconductor chip 750 may have a first surface and a second surface opposite to the first surface. The chip pads 770 may be arranged in the first surface of the semiconductor chip 750. The semiconductor chip 750 may be attached to the top surface of the package substrate 600 in a face-up manner such that the inactive surface of the semiconductor substrate 760 faces the package substrate 600. For example, the plurality of semiconductor chips 750 may be sequentially stacked on the package substrate 600 such that a DAF 755 is attached to the second surface of one of the semiconductor chips 750 and is arranged to be in contact with the top surface of the package substrate 600 below the DAF 755 or the first surface of another semiconductor chip 750 below the DAF 755. A plurality of chip connectors 780 may connect the chip pads 770 to package upper pads corresponding to at least some of the top conductive patterns 632. Each of the chip connectors 780 may correspond to a bonding wire.

The plurality of semiconductor chips 750 may be sequentially stacked to form a stair structure by shifting in a horizontal direction to expose the chip pads 770. The chip connectors 780 may extend to sequentially connect the chip pads 770 from a topmost semiconductor chip 750 to a bottommost semiconductor chip 750 and connect the chip pads 770 of the bottommost semiconductor chip 750 to the top conductive patterns 632.

The top surface of the electronic device 802 may be at a lower vertical level than the top surface of the sub package SPd. For example, the height from the top surface of the package redistribution layer 500 to the top surface of the electronic device 802 may be less than the height from the top surface of the package redistribution layer 500 to the top surface of the sub package SPd.

Although it is illustrated that the second sub package SPc includes two semiconductor chips 750 stacked on each other in FIG. 8 and the sub package SPd includes four semiconductor chips 750 stacked on each other in FIG. 10, embodiments are not limited thereto. The number of semiconductor chips 750 stacked on each other in each of the second sub package SPc and the sub package SPd may be at least 2.

Referring to FIG. 11A, a PiP-type semiconductor package 6 may include the package redistribution layer 500, a plurality of electronic components which are arranged on the package redistribution layer 500 to be apart from each other in a horizontal direction and include the sub package SPd and an electronic device 802a, the package molding layer 900 covering the top surface of the package redistribution layer 500 and surrounding the electronic components, and the package connection terminals 550 attached to the bottom surface of the package redistribution layer 500. The package molding layer 900 may entirely cover the side and top surfaces of each of the sub package SPd and the electronic device 802a.

The electronic device 802a may correspond to a semiconductor chip, e.g., a die, which has not undergone a packaging process. The electronic device 802a may include the component substrate 810 having the active surface and the inactive surface opposite to the active surface, a component device 814 formed on the active surface of the component substrate 810, and a plurality of component pads 822 disposed on the component device 814. The electronic device 802a is substantially similar to the electronic device 802 in FIG. 10, and thus, redundant descriptions thereof may be omitted.

The top surface of the electronic device 802a may be substantially at the same vertical level as the top surface of the sub package SPd. For example, the height from the top surface of the package redistribution layer 500 to the top surface of the electronic device 802a may be substantially the same as the height from the top surface of the package redistribution layer 500 to the top surface of the sub package SPd.

Referring to FIG. 11B, a PiP-type semiconductor package 6a may include the package redistribution layer 500, a plurality of electronic components which are arranged on the package redistribution layer 500 to be apart from each other in a horizontal direction and include the sub package SPd and the electronic device 802a, the package molding layer 900a covering the top surface of the package redistribution layer 500 and surrounding the electronic components, and the package connection terminals 550 attached to the bottom surface of the package redistribution layer 500. The package molding layer 900a may entirely cover the side surface of each of the sub package SPd and the electronic device 802a but may not cover the top surface of the sub package SPd, e.g., the top surface of the sub molding layer 790, and top surface of the electronic device 802a. The top surface of the package molding layer 900a, the top surface of the sub package SPd, and the top surface of the electronic device 802a may be at the same vertical level and coplanar with one another.

In some embodiments, the semiconductor package 6a may further include a heat dissipation unit, which covers the top surface of each of the sub package SPd and the electronic device 802a. The heat dissipation unit may include a heat slug or a heat sink. The semiconductor package 6a may further include a TIM between the heat dissipation unit and the sub package SPd and between the heat dissipation unit and the electronic device 802a. The TIM may be formed as paste or a film.

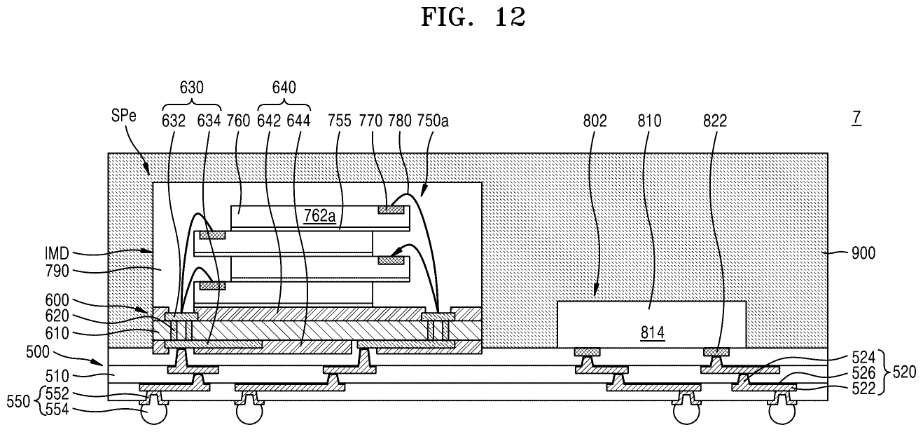

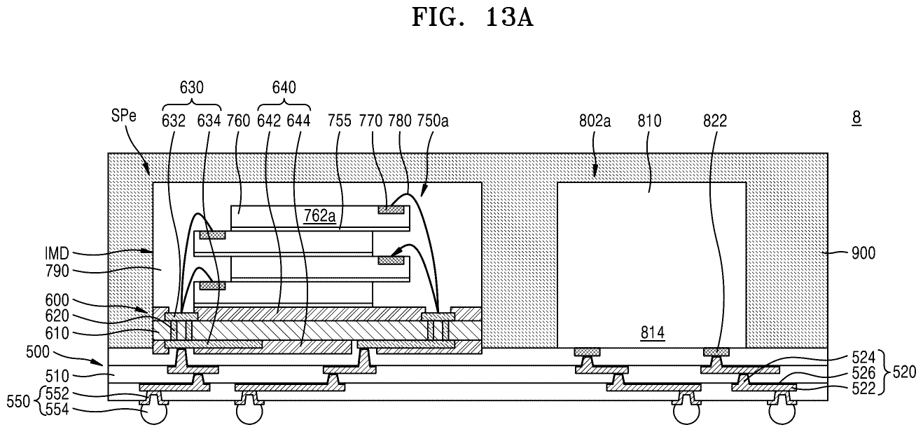

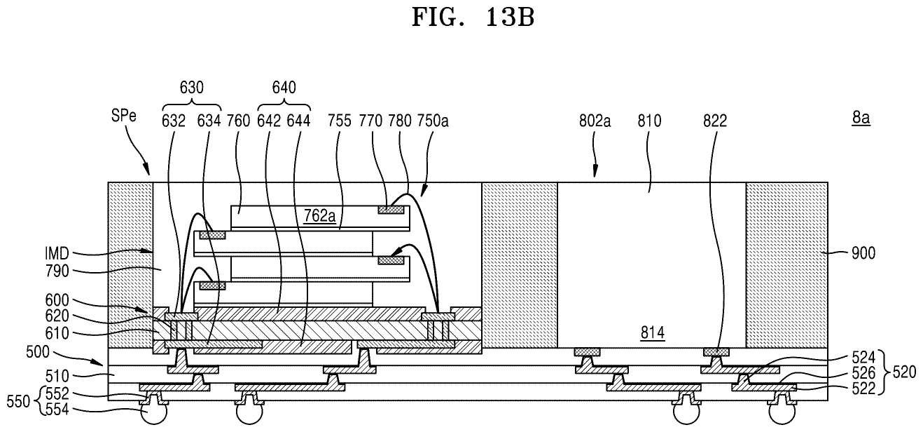

FIGS. 12, 13A, and 13B are cross-sectional views of PiP-type semiconductor packages according to embodiments.

Referring to FIG. 12, a PiP-type semiconductor package 7 may include the package redistribution layer 500, a plurality of electronic components which are arranged on the package redistribution layer 500 to be apart from each other in a horizontal direction and include a sub package SPe and an electronic device 802, the package molding layer 900 covering the top surface of the package redistribution layer 500 and surrounding the electronic components, and the package connection terminals 550 attached to the bottom surface of the package redistribution layer 500. The package molding layer 900 may entirely cover the side and top surfaces of each of the sub package SPe and the electronic device 802.

The electronic device 802 may correspond to a semiconductor chip, e.g., a die, which has not undergone a packaging process. In some embodiments, the electronic device 802 may include a logic device. For example, the electronic device 802 may include a CPU chip, a GPU chip, or an AP chip.

The sub package SPe may include the package substrate 600, a plurality of semiconductor chips 750a sequentially stacked on the package substrate 600, and the sub molding layer 790, which is on the package substrate 600 and covers the semiconductor chips 750a.

Each of the semiconductor chips 750a may include a semiconductor substrate 760 having an active surface and an inactive surface opposite to the active surface, a semiconductor device 762a on the active surface of the semiconductor substrate 760, and a plurality of chip pads 770 in the semiconductor device 762a. In some embodiments, the semiconductor device 762a may correspond to a memory device and each of the semiconductor chips 750a may correspond to a memory semiconductor chip. For example, the semiconductor device 762a may correspond to a volatile memory device including DRAM or SRAM. In some embodiments, each of the semiconductor chips 750a may correspond to a DRAM chip.

In some embodiments, the semiconductor chips 750a may be sequentially stacked in a zigzag pattern by shifting to expose the chip pads 770. The chip connectors 780 may extend to connect the chip pads 770 of each of the semiconductor chips 750a to the top conductive patterns 632. In some embodiments, the semiconductor chips 750a may be stacked to vertically overlap each other, the chip pads 770 of each of the semiconductor chips 750a except for a topmost semiconductor chip 750a may be covered with the DAF 755, and the chip connectors 780 may be connected to the chip pads 770 through the DAF 755.

The top surface of the electronic device 802 may be at a lower vertical level than the top surface of the sub package SPe. For example, the height from the top surface of the package redistribution layer 500 to the top surface of the electronic device 802 may be less than the height from the top surface of the package redistribution layer 500 to the top surface of the sub package SPe.

Referring to FIG. 13A, a PiP-type semiconductor package 8 may include the package redistribution layer 500, a plurality of electronic components which are arranged on the package redistribution layer 500 to be apart from each other in a horizontal direction and include the sub package SPe and the electronic device 802a, the package molding layer 900 covering the top surface of the package redistribution layer 500 and surrounding the electronic components, and the package connection terminals 550 attached to the bottom surface of the package redistribution layer 500. The package molding layer 900 may entirely cover the side and top surfaces of each of the sub package SPe and the electronic device 802a.

The top surface of the electronic device 802a may be substantially at the same vertical level as the top surface of the sub package SPe. For example, the height from the top surface of the package redistribution layer 500 to the top surface of the electronic device 802a may be substantially the same as the height from the top surface of the package redistribution layer 500 to the top surface of the sub package SPe.

Referring to FIG. 13B, a PiP-type semiconductor package 8a may include the package redistribution layer 500, a plurality of electronic components which are arranged on the package redistribution layer 500 to be apart from each other in a horizontal direction and include the sub package SPe and the electronic device 802a, the package molding layer 900a covering the top surface of the package redistribution layer 500 and surrounding the electronic components, and the package connection terminals 550 attached to the bottom surface of the package redistribution layer 500. The package molding layer 900a may entirely cover the side surface of each of the sub package SPe and the electronic device 802a but may not cover the top surface of the sub package SPe, e.g., the top surface of the sub molding layer 790, and top surface of the electronic device 802a. The top surface of the package molding layer 900a, the top surface of the sub package SPe, and the top surface of the electronic device 802a may be at the same vertical level and coplanar with one another.

In some embodiments, the semiconductor package 8a may further include a heat dissipation unit, which covers the top surface of each of the sub package SPe and the electronic device 802a. The heat dissipation unit may include a heat slug or a heat sink. The semiconductor package 8a may further include a TIM between the heat dissipation unit and the sub package SPe and between the heat dissipation unit and the electronic device 802a.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A semiconductor package of a package-in-package type, the semiconductor package comprising:
a package redistribution layer including a plurality of package redistribution patterns and a package redistribution insulating layer surrounding the plurality of package redistribution patterns;
a plurality of electronic components apart from each other in a horizontal direction on the package redistribution layer, the plurality of electronic components include a sub package;
a package molding layer covering a top surface of the package redistribution layer and surrounding the plurality of electronic components; and
a plurality of package connection terminals attached to a bottom surface of the package redistribution layer in a fan-out manner,
the sub package includes a package substrate corresponding to a printed circuit board, a semiconductor chip attached to the package substrate, and a sub molding layer on the package substrate,
the package substrate includes a base insulating layer, package upper pads on a top surface of the base insulating layer and package lower pads on a bottom surface of the base insulating layer,
the semiconductor chip includes a plurality of chip pads electrically connected to the package upper pads,
the sub molding layer covers the semiconductor chip, and
the package lower pads are respectively in contact with and electrically connected to the plurality of package redistribution patterns.

2. The semiconductor package of claim 1, wherein
the plurality of package redistribution patterns include a plurality of package redistribution line patterns, a plurality of package redistribution vias, and a plurality of package redistribution seed layers,
the plurality of package redistribution line patterns are on at least one of a top surface of the package redistribution insulating layer and a bottom surface of the package redistribution insulating layer,
the plurality of package redistribution vias passing through the package redistribution insulating layer and are respectively connected to some of the plurality of package redistribution line patterns,
the plurality of package redistribution seed layers cover the plurality of package redistribution line patterns and the plurality of package redistribution vias, and
the package lower pads are respectively connected to the plurality of package redistribution vias.

3. The semiconductor package of claim 2, wherein some of the plurality of package redistribution seed layers are respectively between the package lower pads and the plurality of package redistribution vias.

4. The semiconductor package of claim 3, wherein
a first portion of each of the package lower pads is in contact with the package redistribution insulating layer, and
a second portion of each of the package lower pads is in contact with a corresponding one of the plurality of package redistribution seed layers.

5. The semiconductor package of claim 2, wherein
the package substrate further includes a bottom solder resist layer,
the bottom solder resist layer covers the bottom surface of the base insulating layer and does not cover the package lower pads,
a package cavity is defined by the bottom solder resist layer and is between a bottommost end of the bottom solder resist layer and a bottom surface of one of the package lower pads, and
the package cavity is completely filled with a portion of one of the plurality of package redistribution vias, a portion of one of the plurality of package redistribution seed layers, and a portion of the package redistribution insulating layer.

6. The semiconductor package of claim 2, wherein
the plurality of package redistribution line patterns include a corresponding package redistribution line pattern,
the plurality of package redistribution vias include a corresponding package redistribution via,
the corresponding package redistribution line pattern forms an integral body with the corresponding package redistribution via,
the corresponding package redistribution via extends from a top surface of the corresponding package redistribution line pattern,
the plurality of package redistribution seed layers include a corresponding package redistribution seed layer, and
the corresponding package redistribution seed layer covers a top surface of the corresponding package redistribution line pattern, a side surface of the corresponding package redistribution via, and a top surface of the corresponding package redistribution via.

7. The semiconductor package of claim 1, wherein
the plurality of electronic components further include an electronic device,
the electronic device includes a component substrate and a plurality of component pads attached to a bottom surface of the component substrate,
the package redistribution insulating layer covers the bottom surface of the component substrate and does not cover a side surface of the component substrate, and
the package molding layer entirely covers the side surface of the component substrate.

8. The semiconductor package of claim 7, wherein the package redistribution insulating layer covers side surfaces of each of the plurality of component pads and bottom surfaces of each of the plurality of component pads.

9. The semiconductor package of claim 1, wherein
the plurality of electronic components further include an electronic device, the electronic device includes a component body and a plurality of component pads at a bottom of the component body,
the package redistribution insulating layer covers a bottom surface of the component body but not a side surface of the component body,
the package molding layer covers the side surface of the component body, and
a top surface of the package redistribution insulating layer, the bottom surface of the component body, and a bottom surface of each of the plurality of component pads are at a same vertical level.

10. The semiconductor package of claim 1, wherein
the package redistribution insulating layer covers a lower side surface of the package substrate, and
the package molding layer covers an upper side surface of the package substrate.

11. A semiconductor package of a package-in-package type, the semiconductor package comprising:
a package redistribution layer including a plurality of package redistribution patterns and a package redistribution insulating layer surrounding the plurality of package redistribution patterns;
a plurality of sub packages apart from each other in a horizontal direction on the package redistribution layer, the plurality of sub packages including two sub packages apart from each other in the horizontal direction on the package redistribution layer;
a package molding layer covering a top surface of the package redistribution layer and surrounding the plurality of sub packages; and
a plurality of package connection terminals attached to a bottom surface of the package redistribution layer in a fan-out manner, wherein
each sub package of the plurality of sub packages includes a package substrate, a semiconductor chip attached to the package substrate, and a sub molding layer on the package substrate,
the package substrate includes a base insulating layer, package upper pads on a top surface of the base insulating layer, package lower pads on a bottom surface of the base insulating layer, and a bottom solder resist layer,
the bottom solder resist layer covers the bottom surface of the base insulating layer and does not cover the package lower pads,
the semiconductor chip includes a plurality of chip pads electrically connected to the package upper pads,
the sub molding layer covers the semiconductor chip,
the package lower pads are respectively in contact with and electrically connected to the plurality of package redistribution patterns, and
a portion of each of the package lower pads is in contact with the package redistribution insulating layer.

12. The semiconductor package of claim 11, wherein
the plurality of package redistribution patterns include a plurality of package redistribution line patterns, a plurality of package redistribution vias, and a plurality of package redistribution seed layers,
the plurality of package redistribution line patterns are on at least one of top surfaces of the package redistribution insulating layer and bottom surfaces of the package redistribution insulating layer,
the plurality of package redistribution vias pass through the package redistribution insulating layer and are respectively connected to some of the plurality of package redistribution line patterns, and
the plurality of package redistribution seed layers cover top surfaces of the plurality of package redistribution line patterns, top surfaces of the plurality of package redistribution vias, and side surfaces of the plurality of package redistribution vias.

13. The semiconductor package of claim 12, wherein
a plurality of package cavities are defined by the bottom solder resist layer between bottommost ends of the bottom solder resistive layer and bottom surfaces of the package lower pads,
portions of the plurality of package redistribution vias extend into the plurality of package cavities from a corresponding one of the plurality of package redistribution patterns and are connected respectively to the package lower pads, and
the corresponding one of the plurality of package redistribution patterns is connected to each of the plurality of package redistribution vias.

14. The semiconductor package of claim 13, wherein
a material of the plurality of package redistribution seed layers is different than a material of the plurality of package redistribution vias and a material of the package lower pads, and
a portion of each of the plurality of package redistribution seed layers is between one of the package lower pads and one of the plurality of package redistribution vias respectively connected to the package lower pads.

15. The semiconductor package of claim 12, wherein
one of the plurality of package redistribution line patterns forms an integral body with a package redistribution via in contact with a top surface of the one of the package redistribution line patterns among the plurality of package redistribution vias.

16. The semiconductor package of claim 15, wherein
each of the plurality of package redistribution vias has a tapered shape having a horizontal width decreasing away from the one of the plurality of package redistribution line patterns that is integral with each of the plurality of package redistribution vias.

17. The semiconductor package of claim 11, wherein
the package redistribution insulating layer covers a lower side surface of the package substrate, and
the package molding layer covers an upper side surface of the package substrate.

18. A semiconductor package of a package-in-package type, the semiconductor package comprising:
a lower package; and
an upper package attached to the lower package, wherein
the lower package includes a first wiring structure, a second wiring structure on the first wiring structure, a lower semiconductor chip between the first wiring structure and the second wiring structure, and an expansion layer surrounding the lower semiconductor chip,
the first wiring structure including a plurality of first redistribution patterns and a plurality of first redistribution insulating layers surrounding the plurality of first redistribution patterns,
the second wiring structure includes a plurality of second redistribution patterns and a plurality of second redistribution insulating layers surrounding the plurality of second redistribution patterns,
the expansion layer electrically connects the plurality of first redistribution patterns to the plurality of second redistribution patterns,
the upper package includes a package redistribution layer including a plurality of package redistribution patterns and a package redistribution insulating layer surrounding the plurality of package redistribution patterns, a plurality of electronic components apart from each other in a horizontal direction on the package redistribution layer and including a sub package, a package molding layer covering a top surface of the package redistribution layer and surrounding the plurality of electronic components, and a plurality of package connection terminals electrically connecting the lower package to the upper package and attached to a bottom surface of the package redistribution layer in a fan-out manner,
the sub package includes a package substrate corresponding to a printed circuit board, a semiconductor chip attached to the package substrate, and a sub molding layer on the package substrate,
the package substrate including a base insulating layer, package upper pads on a top surface of the base insulating layer, package lower pads on a bottom surface of the base insulating layer, a plurality of via patterns passing through the base insulating layer and electrically connecting the package upper pads to the package lower pads, and a bottom solder resist layer covering the bottom surface of the base insulating layer but not covering the package lower pads,
the semiconductor chip includes a plurality of chip pads electrically connected to the package upper pads,
the sub molding layer covers the semiconductor chip, and
the package redistribution insulating layer covers a lower side surface of the package substrate, and
the package molding layer covers an upper side surface of the package substrate.

19. The semiconductor package of claim 18, wherein a first portion of each of the package lower pads is in contact with one of the plurality of package redistribution patterns and a second portion of each of the package lower pads is in contact with the package redistribution insulating layer.

20. The semiconductor package of claim 18, wherein
the plurality of package redistribution patterns include a plurality of package redistribution line patterns, a plurality of package redistribution vias, and a plurality of package redistribution seed layers,
the plurality of package redistribution line patterns are on at least one of top surfaces of the package redistribution insulating layer and bottom surfaces of the package redistribution insulating layer,
the plurality of package redistribution vias pass through the package redistribution insulating layer and are respectively connected to some of the plurality of package redistribution line patterns,
the plurality of package redistribution seed layers cover the plurality of package redistribution line patterns and the plurality of package redistribution vias, and
a width of each of the plurality of via patterns is greater than a width of each of the plurality of package redistribution vias.
